(19) United States
(12) Patent Application Publication
(10) Pub. No.: US 2025/0129205 A1
(43) Pub. Date: Apr. 24, 2025

(54) POLYMER AND THIN FILM TRANSISTOR AND ELECTRONIC DEVICE

(71) Applicant: Samsung Electronics Co., Ltd., Suwon-si (KR)

(72) Inventors: Hyung Jun KIM, Suwon-si (KR); Jiyoung JUNG, Suwon-si (KR); Hyunbum KANG, Suwon-si (KR); Gae Hwang LEE, Suwon-si (KR); Bang Lin LEE, Suwon-si (KR)

(73) Assignee: Samsung Electronics Co., Ltd., Suwon-si (KR)

(21) Appl. No.: 18/634,380

(22) Filed: Apr. 12, 2024

(30) Foreign Application Priority Data
Oct. 23, 2023 (KR) 10-2023-0142054

(51) Int. Cl. C08G 61/12; H10K 10/46

(52) U.S. Cl. CPC C08G 61/126; H10K 10/481; C08G 2261/12

(57) ABSTRACT

Disclosed are a polymer including a first repeating unit represented by Chemical Formula 1 and a second repeating unit represented by Chemical Formula 2, a thin film transistor including the same, and an electronic device.

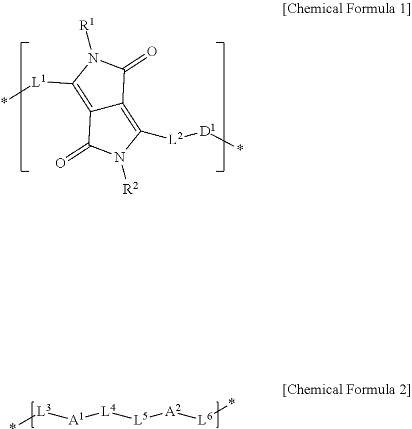

In Chemical Formula 1 or 2, D¹, A¹, A², L¹ to L⁶, R¹, and R² are the same as described in the detailed description.

### CROSS-REFERENCE TO RELATED APPLICATION

This application claims priority to and the benefit of Korean Patent Application No. 10-2023-0142054 filed in the Korean Intellectual Property Office on Oct. 23, 2023, the entire contents of which are incorporated herein by reference.

### BACKGROUND OF THE INVENTION

### (a) Field of the Invention

A polymer, a thin film transistor, and an electronic device are disclosed.

### (b) Description of the Related Art

A flat panel display such as a liquid crystal display (LCD) or an organic light emitting diode (OLED) display may include a thin film transistor (TFT) that is a three-terminal element serving as a switching device or a driving device. The thin film transistor includes a gate electrode, a source electrode, and a drain electrode, and a semiconductor for controlling the current between a source electrode and a drain electrode based on a gate voltage.

The organic thin film transistor (OTFT) includes an organic semiconductor, such as a low molecular compound or polymer, instead of an inorganic semiconductor such as silicon (Si) as a semiconductor material. The OTFT may be made into fibers or films due to the nature of organic materials, and thus has been attracting attention as a core element of flexible display devices, stretchable display devices, and/or the like.

### SUMMARY OF THE INVENTION

Some example embodiments provide a polymer that may be applied to an organic device such as an organic thin film transistor.

Some example embodiments provide a thin film transistor including the polymer.

Some example embodiments provide an electronic device including the polymer or the thin film transistor.

According to some example embodiments, a polymer includes a first repeating unit represented by Chemical Formula 1 and a second repeating unit represented by Chemical Formula 2.

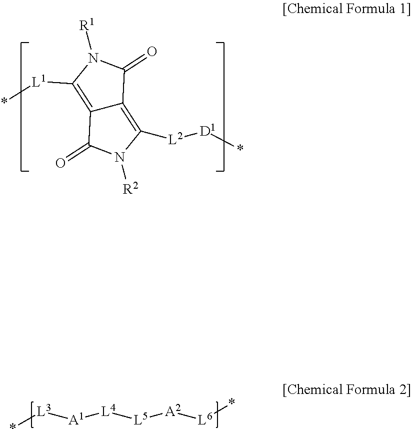

In Chemical Formula 1 and 2,
D¹ is an electron donating moiety,
A¹ and A² are different electron accepting moieties,
L¹ to L⁶ are each independently a single bond, a substituted or unsubstituted C1 to C20 alkylene group, a substituted or unsubstituted C6 to C30 arylene group, a substituted or unsubstituted divalent C3 to C30 heterocyclic group, a fused ring thereof, or a combination thereof,
R1 and R2 are each independently hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C3 to C30 cycloalkenyl group, a substituted or unsubstituted C1 to C30 alkoxy group, a substituted or unsubstituted C3 to C30 cycloheteroalkyl group, a substituted or unsubstituted C3 to C30 cycloheteroalkenyl group, a substituted or unsubstituted C6 to C30 aryl group, a substituted or unsubstituted C7 to C30 alkylaryl group, a substituted or unsubstituted C6 to C30 aryloxy group, a substituted or unsubstituted C3 to C30 heterocyclic group, a halogen, a cyano group, or a combination thereof, and
* is a linking point.

The D¹ may be a substituted or unsubstituted C6 to C30 arylene group; a substituted or unsubstituted divalent C3 to C30 heterocyclic group containing at least one of O, S, Se, Te, or Si; a fused ring thereof; or a combination thereof.

The D¹ may be one or more substituted or unsubstituted phenylene groups; one or more substituted or unsubstituted naphthylene groups; one or more substituted or unsubstituted anthracenylene groups; one or more substituted or unsubstituted phenanthrenylene groups; one or more substituted or unsubstituted pentagonal rings containing at least one of O, S, Se, Te, or Si; a fused ring of one or more of the substituted or unsubstituted pentagonal rings and one or more of the substituted or unsubstituted phenylene groups; a fused ring of one or more of the substituted or unsubstituted pentagonal rings and one or more of the substituted or unsubstituted naphthylene groups; a fused ring of the one or more of the substituted or unsubstituted pentagonal ring and one or more of the substituted or unsubstituted anthracenylene groups; a fused ring of the one or more of the substituted or unsubstituted pentagonal ring and one or more of the substituted or unsubstituted phenanthrenylene groups; or a combination thereof.

The L¹ to L⁶ may each independently be a single bond; a substituted or unsubstituted C6 to C30 arylene group; a substituted or unsubstituted divalent C3 to C30 heterocyclic group containing at least one of N, O, S, Se, Te, or Si; or a combination thereof, and each of the L¹ to L⁶ may be different from the D1.

A¹ and A² may each independently be a C6 to C30 arylene group or a divalent C3 to C30 heterocyclic group containing at least one of nitrogen, carbonyl group, a halogen, or a cyano group.

The A¹ and the A² may each be represented by a substituted or unsubstituted divalent cyclic groups listed in Group 2.

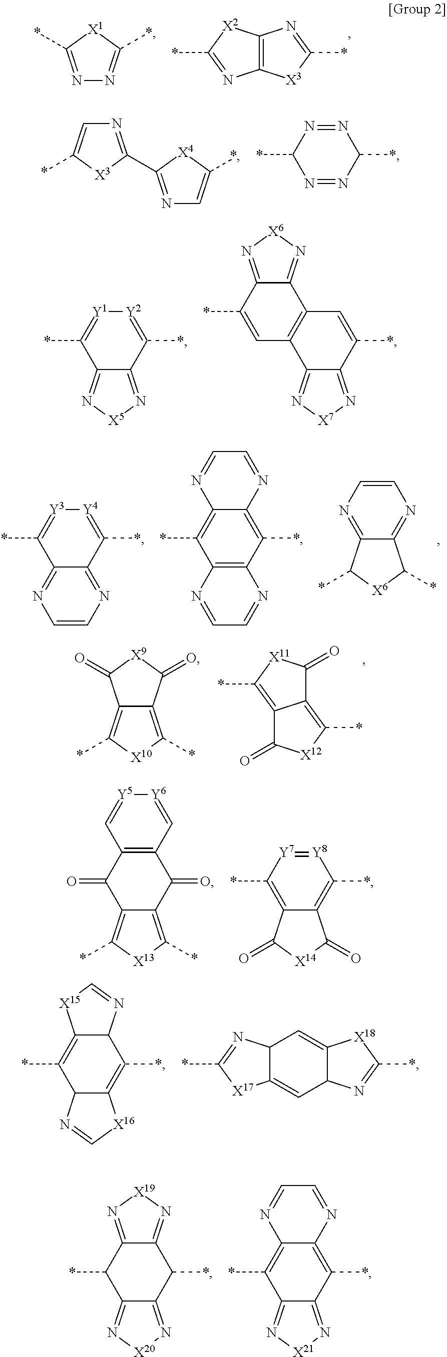

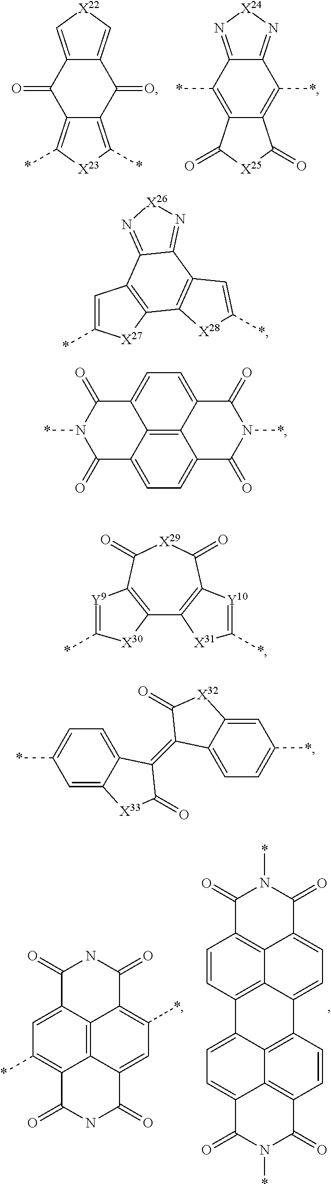

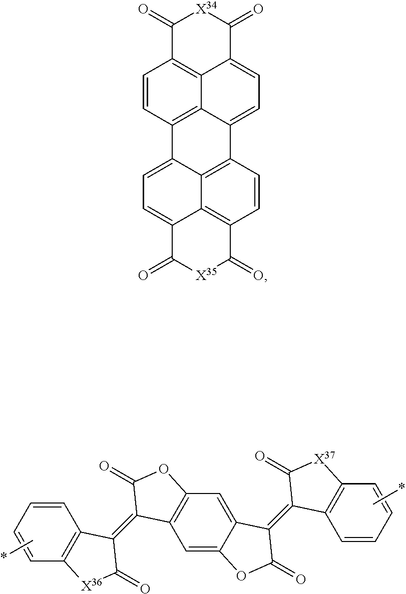

In Group 2,
X¹ to X³⁷ are each independently O, S, Se, Te, NR^{a}, CR^{b}R^{c}, or SiR^{d}R^{e},
Y¹ to Y¹⁰ each independently CR^{f} or N,
R^{a} to R^{f} are each independently hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C3 to C30 cycloalkenyl group, a substituted or unsubstituted C1 to C30 alkoxy group, a substituted or unsubstituted C3 to C30 cycloheteroalkyl group, a substituted or unsubstituted C3 to C30 cycloheteroalkenyl group, a substituted or unsubstituted C6 to C30 aryl group, a substituted or unsubstituted C7 to C30 alkylaryl group, a substituted or unsubstituted C6 to C30 aryloxy group, a substituted or unsubstituted C3 to C30 heterocyclic group, a halogen, a cyano group, or a combination thereof, and * is a linking point.

The second repeating unit may be represented by Chemical Formula 2a.

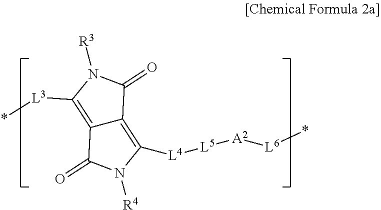

In Chemical Formula 2a,
A² is an electron accepting moiety,
L³ to L⁶ are each independently a single bond, a substituted or unsubstituted C1 to C20 alkylene group, a substituted or unsubstituted C6 to C30 arylene group, a substituted or unsubstituted divalent C3 to C30 heterocyclic group, a fused ring thereof, or a combination thereof,
R³ and R⁴ are each independently hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C3 to C30 cycloalkenyl group, a substituted or unsubstituted C1 to C30 alkoxy group, a substituted or unsubstituted C3 to C30 cycloheteroalkyl group, a substituted or unsubstituted C3 to C30 cycloheteroalkenyl group, a substituted or unsubstituted C6 to C30 aryl group, a substituted or unsubstituted C7 to C30 alkylaryl group, a substituted or unsubstituted C6 to C30 aryloxy group, a substituted or unsubstituted C3 to C30 heterocyclic group, a halogen, a cyano group, or a combination thereof, and
* is a linking point.

The A² may be represented by a substituted or unsubstituted divalent cyclic group listed in Group 2′.

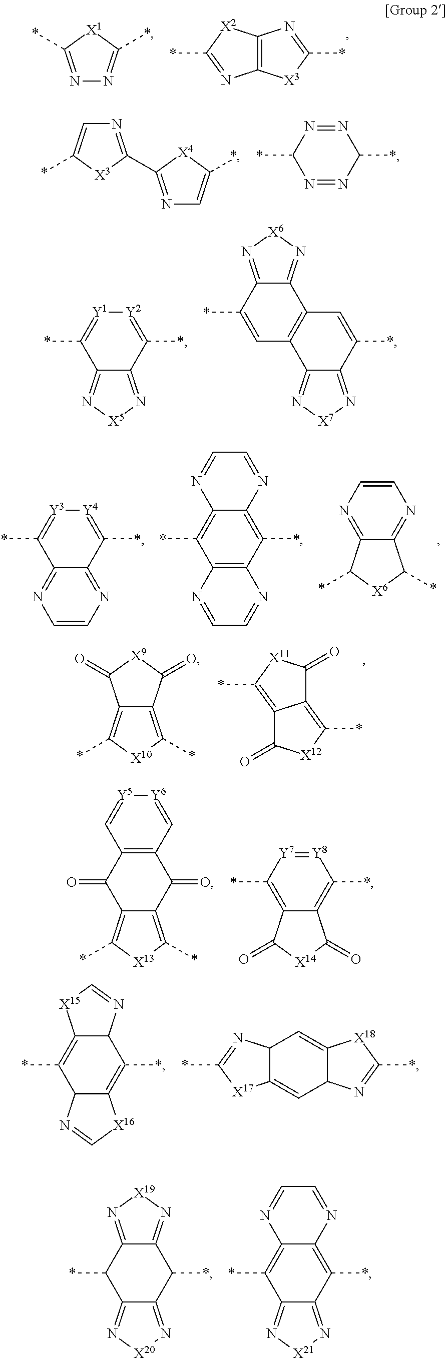

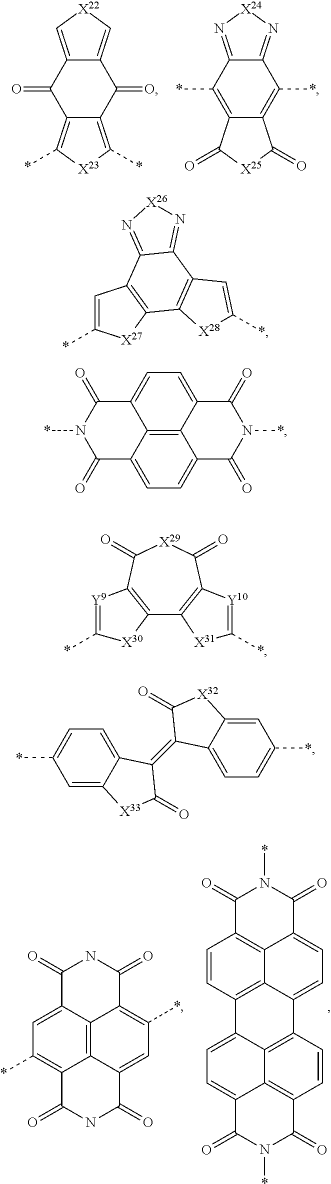

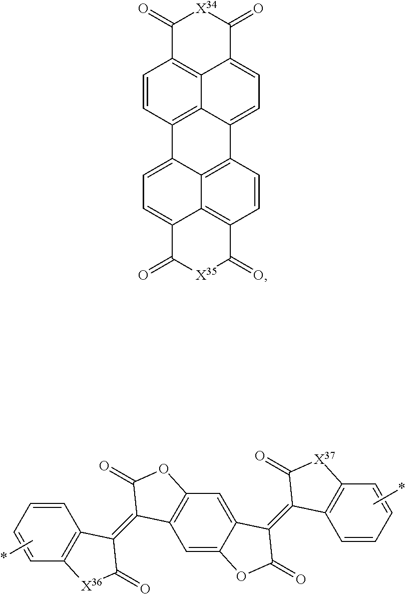

In Group 2′,
X¹ to X¹⁰ and X¹³ to X³⁷ are each independently O, S, Se, Te, NR^{a}, CR^{b}R^{c}, or SiR^{d}R^{e},
Y¹ to Y¹⁰ are each independently CR^{f} or N,
R^{a} to R^{f} are each independently hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C3 to C30 cycloalkenyl group, a substituted or unsubstituted C1 to C30 alkoxy group, a substituted or unsubstituted C3 to C30 cycloheteroalkyl group, a substituted or unsubstituted C3 to C30 cycloheteroalkenyl group, a substituted or unsubstituted C6 to C30 aryl group, a substituted or unsubstituted C7 to C30 alkylaryl group, a substituted or unsubstituted C6 to C30 aryloxy group, a substituted or unsubstituted C3 to C30 heterocyclic group, a halogen, a cyano group, or a combination thereof, and
* is a linking point.

The second repeating unit may be represented by Chemical Formula 2aa.

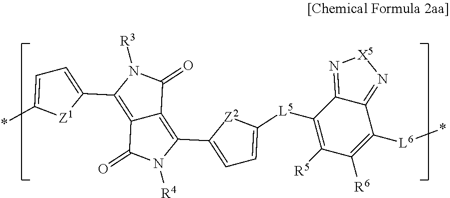

In Chemical Formula 2aa,
X⁵, Z¹, and Z² are each independently O, S, Se, Te, NR^{a}, CR^{b}R^{c}, or SiR^{d}R^{e},
L⁵ and L⁶ are each independently a single bond, a substituted or unsubstituted C1 to C20 alkylene group, a substituted or unsubstituted C6 to C30 arylene group, a substituted or unsubstituted divalent C3 to C30 heterocyclic group, a fused ring thereof, or a combination thereof,
R³ to R⁶ and R^{a} to R^{e} are each independently hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C3 to C30 cycloalkenyl group, a substituted or unsubstituted C1 to C30 alkoxy group, a substituted or unsubstituted C3 to C30 cycloheteroalkyl group, a substituted or unsubstituted C3 to C30 cycloheteroalkenyl group, a substituted or unsubstituted C6 to C30 aryl group, a substituted or unsubstituted C7 to C30 alkylaryl group, a substituted or unsubstituted C6 to C30 aryloxy group, a substituted or unsubstituted C3 to C30 heterocyclic group, a halogen, a cyano group, or a combination thereof, and
* is a linking point.

The first repeating unit and the second repeating unit may be randomly arranged in a polymer chain, and a quantity of the second repeating unit may be less than a quantity of the first repeating unit.

The second repeating unit may be included in an amount of about 1 to about 30 mol % based on a total of the first repeating unit and the second repeating unit.

The polymer may be represented by Chemical Formula 3.

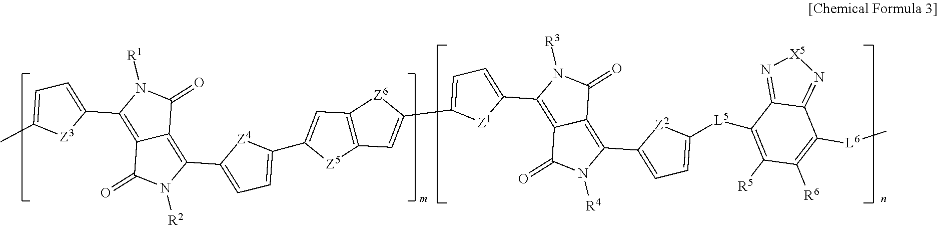

In Chemical Formula 3,
X⁵ and Z¹ to Z⁶ are each independently O, S, Se, Te, NR^{a}, CR^{b}R^{c}, or SiR^{d}R^{e},
L⁵ and L⁶ are each independently a single bond, a substituted or unsubstituted C1 to C20 alkylene group, a substituted or unsubstituted C6 to C30 arylene group, a substituted or unsubstituted divalent C3 to C30 heterocyclic group, a fused ring thereof, or a combination thereof,
R¹ to R⁶ and R^{a} to R^{e} are each independently hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C3 to C30 cycloalkenyl group, a substituted or unsubstituted C1 to C30 alkoxy group, a substituted or unsubstituted C3 to C30 cycloheteroalkyl group, a substituted or unsubstituted C3 to C30 cycloheteroalkenyl group, a substituted or unsubstituted C6 to C30 aryl group, a substituted or unsubstituted C7 to C30 alkylaryl group, a substituted or unsubstituted C6 to C30 aryloxy group, a substituted or unsubstituted C3 to C30 heterocyclic group, a halogen, a cyano group, or a combination thereof, and
0.7≤m<1.0 and 0<n≤0.3.

According to some example embodiments, a polymer includes a first repeating unit including a first electron accepting moiety and an electron donating moiety; and a second repeating unit including the first electron accepting moiety and a second electron accepting moiety different from the first electron accepting moiety, wherein the first repeating unit and the second repeating unit are randomly arranged in a chain, and a quantity of the second repeating unit is less than a quantity of the first repeating unit.

The first electron accepting moiety and the second electron accepting moiety may each be represented by the substituted or unsubstituted divalent cyclic groups listed in Group 2.

The electron donating moiety may be one or more substituted or unsubstituted phenylene groups; one or more substituted or unsubstituted naphthylene groups; one or more substituted or unsubstituted anthracenylene groups; one or more substituted or unsubstituted phenanthrenylene groups; one or more substituted or unsubstituted pentagonal rings containing at least one of O, S, Se, Te, or Si; a fused ring of one or more of the substituted or unsubstituted pentagonal rings and one or more of the substituted or unsubstituted phenylene groups; a fused ring of the one or more of the substituted or unsubstituted pentagonal rings and one or of the more substituted or unsubstituted naphthylene groups; a fused ring of one or more of the substituted or unsubstituted pentagonal ring and one or more of the substituted or unsubstituted anthracenylene groups; a fused ring of one or more of the substituted or unsubstituted pentagonal ring and one or more of the substituted or unsubstituted phenanthrenylene groups; or a combination thereof.

A molar ratio of the first repeating unit and the second repeating unit may be within a range of about 70:30 to about 99:1.

A total molar ratio of the first electron accepting moiety and the second electron accepting moiety in the polymer may be within a range of about 1.01 to 3 times a molar ratio of the electron donating moiety in the polymer.

According to some example embodiments, an electronic device including a semiconductor layer including the polymer is provided.

According to some example embodiments, a thin film transistor includes a gate electrode, an organic semiconductor overlapping the gate electrode, and a source electrode and a drain electrode electrically connected to the organic semiconductor, wherein the organic semiconductor includes the polymer.

According to some example embodiments, an electronic device including the thin film transistor is provided.

The polymer may be applied to organic devices such as organic thin film transistors to improve electrical characteristics.

### BRIEF DESCRIPTION OF THE DRAWINGS

FIGS. 1 to 3 are cross-sectional views each showing thin film transistors according to some example embodiments;

FIG. 4 is a graph showing the light absorption characteristics of polymer films according to Preparation Examples 1 and 2 and Reference Preparation Example;

FIG. 5 is a circuit diagram of an inverter according to at least one example embodiment; and

FIG. 6 is a block diagram of an electronic device according to at least one example embodiment.

### DETAILED DESCRIPTION OF THE EMBODIMENTS

Example embodiments will hereinafter be described in detail, and may be easily performed by those who have common knowledge in the related art. However, this disclosure may be embodied in many different forms and is not to be construed as limited to the example embodiments set forth herein.

In the drawings, the thickness of layers, films, panels, regions, etc., are not too scale and may be exaggerated for clarity.

It will be understood that when an element such as a layer, film, region, or substrate is referred to as being “on” another element, it may be directly on the other element or intervening elements may also be present. In contrast, when an element is referred to as being “directly on” another element, there are no intervening elements present. Additionally, it will be understood that spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly.

As used herein, when a definition is not otherwise provided, “substituted” refers to replacement of hydrogen of a compound by a substituent selected from a halogen, a hydroxy group, a nitro group, a cyano group, an amino group, an azido group, an amidino group, a 16ydrazine group, a hydrazono group, a carbonyl group, a carbamyl group, a thiol group, an ester group, a carboxyl group or a salt thereof, a sulfonic acid group or a salt thereof, a phosphoric acid group or a salt thereof, a C1 to C30 alkyl group, a C2 to C30 alkenyl group, a C2 to C30 alkynyl group, a C6 to C30 aryl group, a C7 to C30 arylalkyl group, a C1 to C30 alkoxy group, a C1 to C20 heteroalkyl group, a C3 to C20 heterocyclic group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, and/or a combination thereof.

As used herein, when a definition is not otherwise provided, “hetero” refers to one including 1 to 4 heteroatoms selected from N, O, S, Se, Te, Si, and P.

As used herein, when a definition is not otherwise provided, “alkyl group” is a linear or branched saturated monovalent hydrocarbon group (e.g., a methyl group, an ethyl group, a propyl group, an isobutyl group, a sec-butyl group, a tert-butyl group, a pentyl group, an iso-amyl group, a hexyl group, and/or the like).

As used herein, when a definition is not otherwise provided, “alkoxy group” refers to an alkyl group that is linked via an oxygen, e.g., a methoxy group, an ethoxy group, a sec-butyloxy group, and/or the like.

As used herein, when a definition is not otherwise provided, “aryl group” refers to a monovalent functional group formed by the removal of one hydrogen atom from one or more rings of an arene, e.g., phenyl or naphthyl. The arene refers to a hydrocarbon having an aromatic ring, and includes monocyclic and polycyclic hydrocarbons wherein the additional ring(s) of the polycyclic hydrocarbon may be aromatic or nonaromatic.

As used herein, when a definition is not otherwise provided, “heterocyclic group” includes at least one heteroatom such as N, O, S, Se, Te, Si, or P in a ring such as an aryl group, a cycloalkyl group, a fused ring thereof, or a combination thereof, and the remaining carbon. When the heterocyclic group is a fused ring, a heteroatom may be included in the entire heterocyclic group or at least one of the rings.

As used herein, when a definition is not otherwise provided, “aromatic ring” refers to a functional group in which all atoms in the cyclic functional group have a p-orbital, and wherein these p-orbitals are conjugated. For example, the aromatic ring may be a C6 to C30 aryl group.

Hereinafter, a polymer according to some example embodiments is described.

The polymer according to some example embodiments may be a semiconducting polymer and/or copolymer including moieties with different electrical characteristics.

The polymer and/or copolymer (hereafter jointly “polymer” for brevity) may include a first repeating unit and a second repeating unit.

The first repeating unit may be a semiconducting repeating unit having an electron donating moiety and an electron accepting moiety, and may exhibit semiconductor characteristics through an interaction between the electron donating moiety and the electron accepting moiety. The electron donating moiety and the electron accepting moiety may be directly linked or indirectly linked through a linking group.

The second repeating unit may include different electron accepting moieties, for example, a first electron accepting moiety and a second electron accepting moiety having different structures. The first electron accepting moiety and the second electron accepting moiety may be directly linked or indirectly linked through a linking group.

The electron donating moiety included in the first repeating unit may be a moiety with electron donating properties, such as a substituted or unsubstituted C6 to C30 arylene group; a substituted or unsubstituted divalent C3 to C30 heterocyclic group containing at least one of N, O, S, Se, Te, or Si; a fused ring thereof; and/or a combination thereof. For example, the electron donating moiety may be one or more substituted or unsubstituted phenylene groups; one or more substituted or unsubstituted naphthylene groups; one or more substituted or unsubstituted anthracenylene groups; one or more substituted or unsubstituted phenanthrenylene groups; a fused ring of one or more of the substituted or unsubstituted pentagonal rings containing at least one of O, S, Se, Te, or Si; a fused ring of one or more of the substituted or unsubstituted pentagonal rings and one or more substituted or unsubstituted phenylene groups; a fused ring of one or more of the substituted or unsubstituted pentagonal rings and one or more substituted or unsubstituted naphthylene groups; a fused ring of one or more of the substituted or unsubstituted pentagonal ring and one or more substituted or unsubstituted anthracenylene groups; a fused ring of one or more of the substituted or unsubstituted pentagonal ring and one or more substituted or unsubstituted phenanthrenylene groups; and/or a combination thereof.

The electron donating moiety included in the first repeating unit may be, for example, one of the substituted or unsubstituted moieties listed in Group 1, but is not limited thereto.

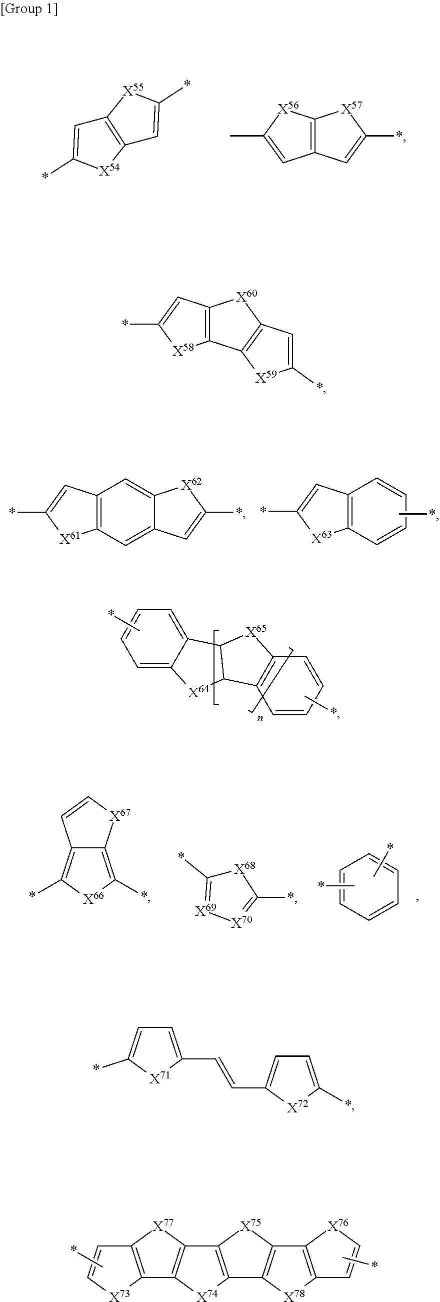

In Group 1,
X⁵⁴ to X⁵⁹, X⁶¹ to X⁶⁸, and X⁷¹ to X⁷⁶ are each independently O, S, Se, or Te;
X⁶⁰, X⁷⁷, and X⁷⁸ are each independently O, S, Se, Te, NR^{g}, CR^{h}Rⁱ, or SiR^{j}R^{k};
X⁶⁹ and X⁷⁰ are each independently N, CR^{l}, or SiR^{m};
R^{g} to R^{m} are each independently hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C3 to C30 cycloalkenyl group, a substituted or unsubstituted C1 to C30 alkoxy group, a substituted or unsubstituted C3 to C30 cycloheteroalkyl group, a substituted or unsubstituted C3 to C30 cycloheteroalkenyl group, a substituted or unsubstituted C6 to C30 aryl group, a substituted or unsubstituted C7 to C30 alkylaryl group, a substituted or unsubstituted C6 to C30 aryloxy group, a substituted or unsubstituted C3 to C30 heterocyclic group, a halogen, a cyano group, and/or a combination thereof;
n is 0, 1, or 2; and
* is a linking point.

In at least one embodiment, one or more of the hydrogens of each divalent cyclic group listed in Group 1 may be substituted with a monovalent substituent. The monovalent substituent may be for example substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C3 to C30 cycloalkenyl group, a substituted or unsubstituted C1 to C30 alkoxy group, a substituted or unsubstituted C3 to C30 cycloheteroalkyl group, a substituted or unsubstituted C3 to C30 cycloheteroalkenyl group, a substituted or unsubstituted C6 to C30 aryl group, a substituted or unsubstituted C7 to C30 alkylaryl group, a substituted or unsubstituted C6 to C30 aryloxy group, a substituted or unsubstituted C3 to C30 heterocyclic group, a halogen, a cyano group, and/or a combination thereof; but is not limited thereto.

In at least one embodiment, the electron accepting moiety included in the first repeating unit and at least one of the first and second electron accepting moieties included in the second repeating unit may be the same and/or selected from the same Group. For example, in at least one embodiment, the electron accepting moiety included in the first repeating unit and at least one of the first and second electron accepting moieties included in the second repeating unit may be, for example, a C6 to C30 arylene group or a divalent C3 to C30 heterocyclic group containing at least one of nitrogen, carbonyl group, a halogen, or a cyano group. For example, the electron accepting moiety included in the first repeating unit and/or at least one of the first and second electron accepting moieties included in the second repeating unit may each be selected from the substituted or unsubstituted divalent cyclic groups listed in Group 2, but is not limited thereto.

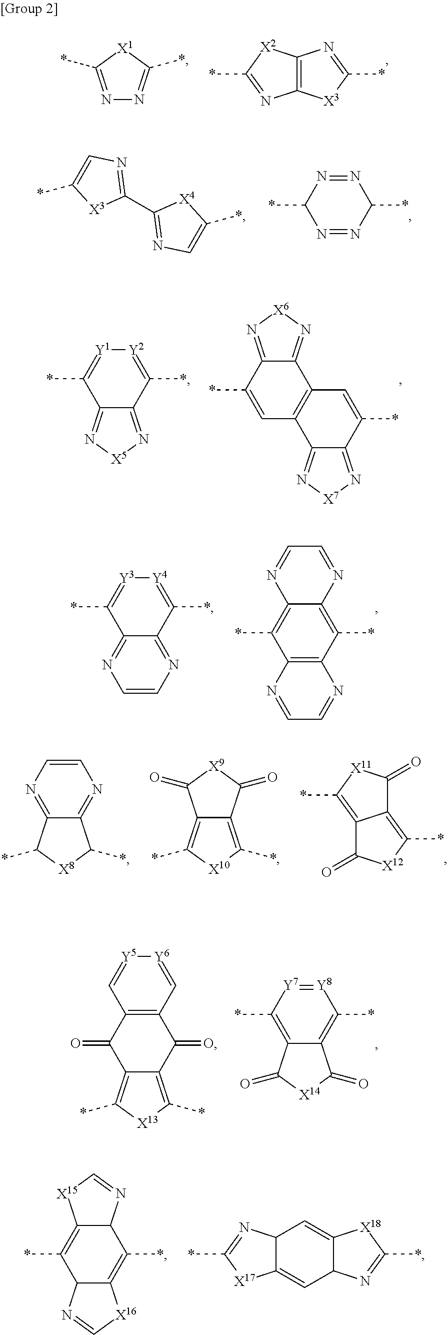

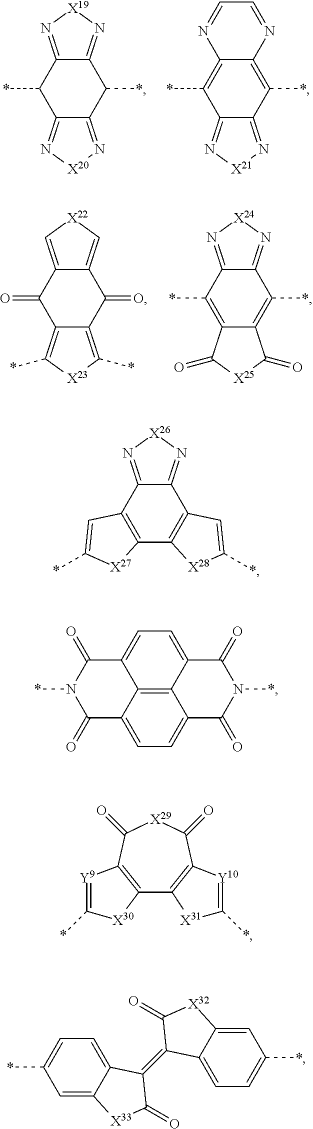

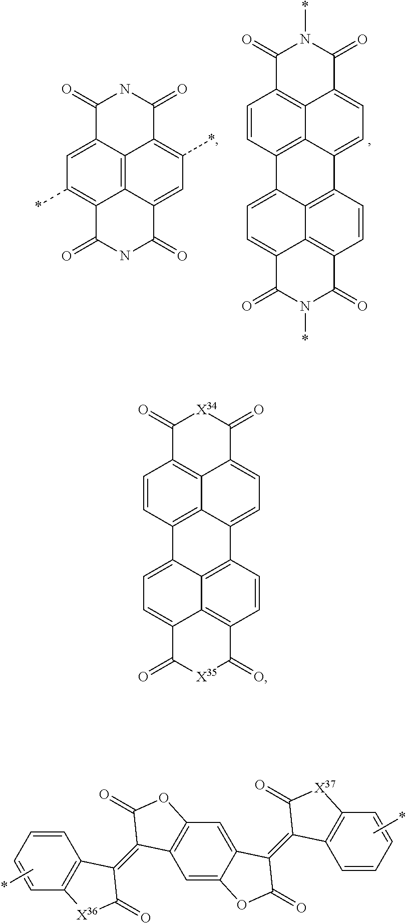

In Group 2,
X¹ to X³⁷ may the same as or different from each other and may each independently be O, S, Se, Te, NR^{a}, CR^{b}R^{c}, or SiR^{d}R^{e};
Y¹ to Y¹⁰ may be the same as or different from each other and may each independently be CR^{f} or N;
R^{a} to R^{f} may each independently be hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C3 to C30 cycloalkenyl group, a substituted or unsubstituted C1 to C30 alkoxy group, a substituted or unsubstituted C3 to C30 cycloheteroalkyl group, a substituted or unsubstituted C3 to C30 cycloheteroalkenyl group, a substituted or unsubstituted C6 to C30 aryl group, a substituted or unsubstituted C7 to C30 alkylaryl group, a substituted or unsubstituted C6 to C30 aryloxy group, a substituted or unsubstituted C3 to C30 heterocyclic group, a halogen, a cyano group, and/or a combination thereof; and
* may be a linking point.

At least one hydrogen of each divalent cyclic group listed in Group 2 may be substituted with a monovalent substituent. The monovalent substituent may be, for example, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C3 to C30 cycloalkenyl group, a substituted or unsubstituted C1 to C30 alkoxy group, a substituted or unsubstituted C3 to C30 cycloheteroalkyl group, a substituted or unsubstituted C3 to C30 cycloheteroalkenyl group, a substituted or unsubstituted C6 to C30 aryl group, a substituted or unsubstituted C7 to C30 alkylaryl group, a substituted or unsubstituted C6 to C30 aryloxy group, a substituted or unsubstituted C3 to C30 heterocyclic group, a halogen, a cyano group, or a combination thereof, but is not limited thereto. For example, the monovalent substituent may be a halogen selected from F, Cl, Br or I; a cyano group; and/or a combination thereof.

The electron donating moiety and the electron accepting moiety in the first repeating unit may be included in a molar ratio of substantially about 1:1, and thus the first repeating unit may theoretically have neutral electrical characteristics. Because the first and second electron accepting moieties in the second repeating unit each have a negative charge, the second repeating unit may have negative electrical characteristics.

The first repeating unit and the second repeating unit may be arranged randomly in the polymer, and the polymer may have theoretically partially negative electrical characteristics due to the inclusion of the first repeating unit with neutral electrical characteristics and the second repeating unit with negative electrical characteristics. Therefore, electron deficiency may occur within the polymer, and as a result, intra-molecular charge transfer along the polymer chain may increase, thereby improving hole mobility.

In addition, the first repeating unit and the second repeating unit may strengthen an interaction between adjacent polymers. For example, the inter-molecular holes mobility may also be increased by increasing inter-molecular charge transfer between the second repeating unit of a polymer with negative electrical characteristics and the electron donating moiety of an adjacent polymer with positive electrical characteristics.

Therefore, charge carrier mobility (e.g., hole mobility) within a polymer film including the polymer may be effectively improved.

In at least one embodiment, the second repeating unit may be included in smaller quantities than the first repeating unit. Accordingly, the push-pull characteristics between the electron donating moiety and the electron accepting moiety in the first repeating unit may be sufficiently maintained to exhibit good semiconductor characteristics, while electrical characteristics may be effectively improved by improving charge mobility due to the aforementioned intra-molecular charge transfer and/or inter-molecular charge transfer.

For example, the second repeating unit may be included in an amount of less than or equal to about 30 mol % based on a total of the first repeating unit and the second repeating unit. By including the second repeating unit within the above range, the effects of improving the semiconductor characteristics and charge mobility of the aforementioned polymer may be further balanced. The second repeating unit may be included in an amount of, within the above range, for example, about 1 to about 30 mol %, about 3 to about 30 mol %, about 5 to about 30 mol %, about 7 to about 30 mol %, about 10 to about 30 mol %, about 1 to about 28 mole %, about 3 to about 28 mole %, about 5 to about 28 mole %, about 7 to about 28 mole %, about 10 to about 28 mole %, about 1 to 25 mole %, about 3 to about 25 mole %, about 5 to about 25 mole %, about 7 to about 25 mol %, about 10 to about 25 mol %, about 1 to about 20 mol %, about 3 to about 20 mol %, about 5 to about 20 mol %, about 7 to about 20 mol %, about 10 to about 20 mol %, about 1 to about 15 mol %, about 3 to about 15 mol %, about 5 to about 15 mol %, about 7 to about 15 mol %, and/or about 10 to about 15 mol %.

For example, a molar ratio of the first repeating unit and the second repeating unit may be about 70:30 to about 99:1, and within this range, about 75:25 to about 95:5, and/or about 80:20 to about 90:10.

In at least one example embodiment, the electron accepting moiety included in the first repeating unit may be the same as the first electron accepting moiety included in the second repeating unit, and accordingly, the first repeating unit and the second repeating unit may include a first electron accepting moiety in common.

For example, the polymer may include the second repeating unit, and thus it may have a higher ratio of electron accepting moieties than electron donating moieties in the polymer. For example, when the first repeating unit and the second repeating unit commonly include a first electron accepting moiety, a total molar ratio of the first electron accepting moiety and the second electron accepting moiety in the polymer may be about 1.01 times or more, and within the above range, about 1.02 times or more, about 1.05 times or more, about 1.1 times or more, about 1.15 times or more, about 1.2 times or more, about 1.3 times or more, about 1.5 times or more, or about 1.8 times or more, for example about 1.01 times to about 3 times, about 1.02 times to about 3 times, about 1.05 times to about 3 times, about 1.1 times to about 3 times, about 1.15 times to about 3 times, about 1.2 times to about 3 times, about 1.3 times to about 3 times, about 1.5 times to about 3 times, about 1.8 times to about 3 times, about 1.01 times to about 2.5 times, about 1.02 times to about 2.5 times, about 1.05 times to about 2.5 times, about 1.1 times to about 2.5 times, about 1.15 times to about 2.5 times, about 1.2 times to about 2.5 times, about 1.3 times to about 2.5 times, about 1.5 times to about 2.5 times, about 1.8 times to about 2.5 times, about 1.01 times to about 2 times, about 1.02 times to about 2 times, about 1.05 times to about 2 times to about 2 times, about 1.1 times to about 2 times, about 1.15 times to about 2 times, about 1.2 times to about 2 times, about 1.3 times to about 2 times, about 1.5 times to about 2 times, and/or about 1.8 times to about 2 times, relative to a molar ratio of electron donating moiety in the polymer.

As an example, the polymer may include a first repeating unit represented by Chemical Formula 1 below and a second repeating unit represented by Chemical Formula 2.

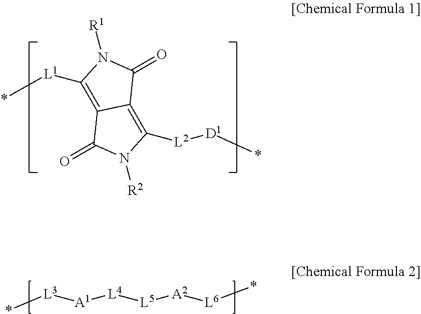

In Chemical Formulae 1 and 2,
D¹ is an electron donating moiety;
A¹ and A² are different electron accepting moieties (e.g., the first electron accepting moiety and the second electron accepting moiety);
L¹ to L⁶ are each independently a single bond, a substituted or unsubstituted C1 to C20 alkylene group, a substituted or unsubstituted C6 to C30 arylene group, a substituted or unsubstituted divalent C3 to C30 heterocyclic group, a fused ring thereof, and/or a combination thereof;
R¹ and R² are each independently hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C3 to C30 cycloalkenyl group, a substituted or unsubstituted C1 to C30 alkoxy group, a substituted or unsubstituted C3 to C30 cycloheteroalkyl group, a substituted or unsubstituted C3 to C30 cycloheteroalkenyl group, a substituted or unsubstituted C6 to C30 aryl group, a substituted or unsubstituted C7 to C30 alkylaryl group, a substituted or unsubstituted C6 to C30 aryloxy group, a substituted or unsubstituted C3 to C30 heterocyclic group, a halogen, a cyano group, and/or a combination thereof; and
* is a linking point.

For example, D¹ may be a substituted or unsubstituted C6 to C30 arylene group; A substituted or unsubstituted divalent C3 to C30 heterocyclic group containing at least one of O, S, Se, Te, or Si; a fused ring thereof; or a combination thereof, for example one or more substituted or unsubstituted phenylene groups; one or more substituted or unsubstituted naphthylene groups; one or more substituted or unsubstituted anthracenylene groups; one or more substituted or unsubstituted phenanthrenylene groups; a fused ring of one or more of the substituted or unsubstituted pentagonal rings containing at least one of O, S, Se, Te, or Si; a fused ring of one or more of the substituted or unsubstituted pentagonal rings and one or more substituted or unsubstituted phenylene groups; a fused ring of one or more of the substituted or unsubstituted pentagonal rings and one or more substituted or unsubstituted naphthylene groups; a fused ring of one or more of the substituted or unsubstituted pentagonal ring and one or more substituted or unsubstituted anthracenylene groups; a fused ring of one or more of the substituted or unsubstituted pentagonal ring and one or more substituted or unsubstituted phenanthrenylene groups; and/or a combination thereof. For example, D¹ may be selected from the substituted or unsubstituted divalent cyclic groups listed in Group 1.

L¹ to L⁶ may each be a linking group and may each be different from D¹. For example, L¹ to L⁶ may each independently be a single bond; a substituted or unsubstituted C6 to C30 arylene group; a substituted or unsubstituted divalent C3 to C30 heterocyclic group containing at least one of N, O, S, Se, Te, or Si; and/or a combination thereof. For example, L¹ to L⁶ may each independently be a divalent linking group including a single bond; at least one substituted or unsubstituted furan; at least one substituted or unsubstituted thiophene; at least one substituted or unsubstituted selenophene; at least one substituted or unsubstituted tellurophene; at least one substituted or unsubstituted pyrrole; at least one substituted or unsubstituted benzene; or a fused ring in which two or more selected from these are fused; and/or a combination thereof.

For example, L¹ to L⁶ may each independently be one substituted or unsubstituted benzene; at least one substituted or unsubstituted furan; at least one substituted or unsubstituted thiophene; at least one substituted or unsubstituted selenophene; at least one substituted or unsubstituted tellurophene; at least one substituted or unsubstituted naphthalene; at least one substituted or unsubstituted anthracene; at least one substituted or unsubstituted tetracene; a fused ring of at least one substituted or unsubstituted benzene and at least one substituted or unsubstituted furan; a fused ring of at least one substituted or unsubstituted benzene and at least one substituted or unsubstituted thiophene; a fused ring of at least one substituted or unsubstituted benzene and at least one substituted or unsubstituted selenophene; or a fused ring of at least one substituted or unsubstituted benzene and at least one substituted or unsubstituted tellurophene, but are not limited thereto.

As an example, A¹ and A² may each independently be a C6 to C30 arylene group or a divalent C3 to C30 heterocyclic group containing at least one of nitrogen, carbonyl, a halogen, or a cyano group, and for example, each may be selected from the substituted or unsubstituted divalent ring groups listed in Group 2.

As an example, the second repeating unit may include an electron accepting moiety (first electron accepting moiety) in common with the first repeating unit, and the first repeating unit and the second repeating unit may have a substituted or unsubstituted a diketopyrrolopyrrole moiety in common.

As an example, the second repeating unit may be represented by Chemical Formula 2a.

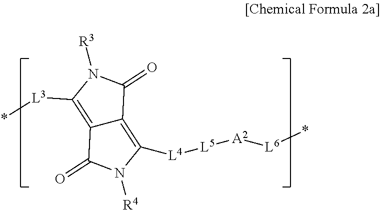

In Chemical Formula 2a,
A² is a second electron accepting moiety;
L³ to L⁶ are each independently a single bond, a substituted or unsubstituted C1 to C20 alkylene group, a substituted or unsubstituted C6 to C30 arylene group, a substituted or unsubstituted divalent C3 to C30 heterocyclic group, a fused ring thereof, and/or a combination thereof;
R³ and R⁴ are each independently hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C3 to C30 cycloalkenyl group, a substituted or unsubstituted C1 to C30 alkoxy group, a substituted or unsubstituted C3 to C30 cycloheteroalkyl group, a substituted or unsubstituted C3 to C30 cycloheteroalkenyl group, a substituted or unsubstituted C6 to C30 aryl group, a substituted or unsubstituted C7 to C30 alkylaryl group, a substituted or unsubstituted C6 to C30 aryloxy group, a substituted or unsubstituted C3 to C30 heterocyclic group, a halogen, a cyano group, and/or a combination thereof; and
* is a linking point.

For example, R³ in Chemical Formula 2a may be the same as R¹ in Chemical Formula 1, and R⁴ in Chemical Formula 2a may be the same as R² in Chemical Formula 1.

For example, L³ in Chemical Formula 2a may be the same as L¹ in Chemical Formula 1, and L⁴ in Chemical Formula 2a may be the same as L² in Chemical Formula 1.

For example, A² in Chemical Formula 2a may be selected from the substituted or unsubstituted divalent ring groups listed in Group 2′, but is not limited thereto.

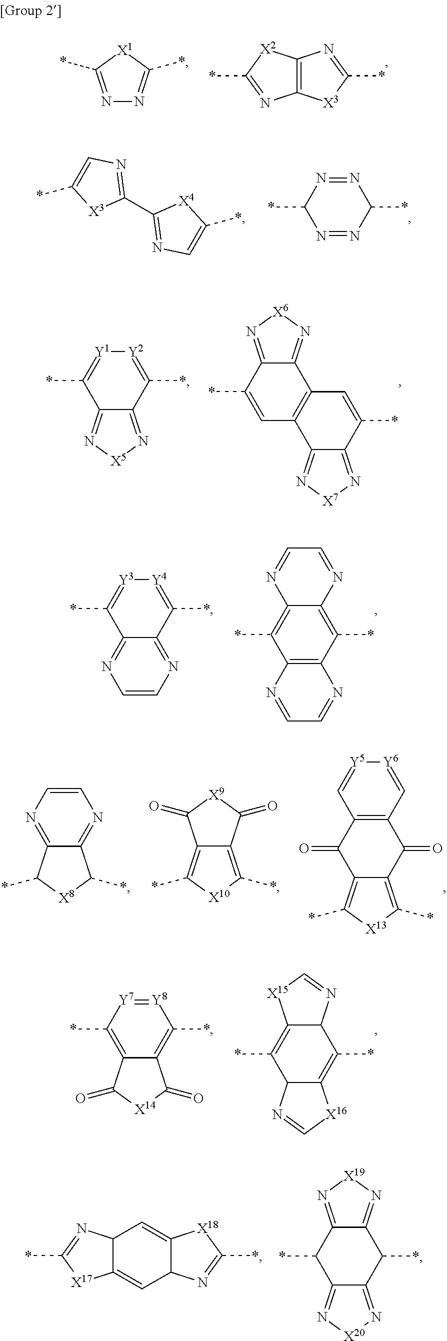

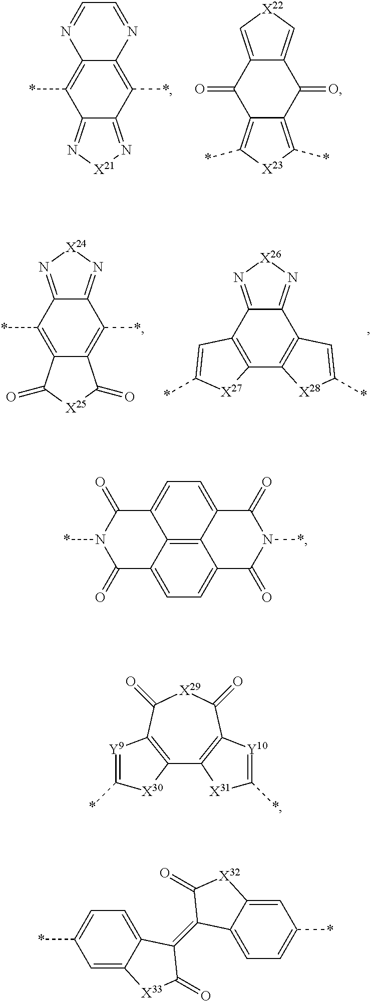

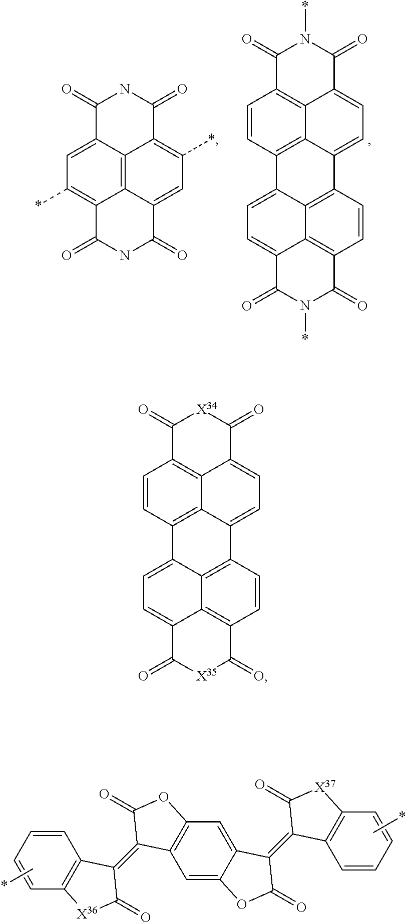

In Group 2′, X¹ to X¹⁰, X¹³ to X³⁷ and Y¹ to Y¹⁰ are the same as described above. At least one hydrogen of the divalent cyclic group listed in Group 2′ may be substituted with a monovalent substituent. The monovalent substituent may be, for example, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C3 to C30 cycloalkenyl group, a substituted or unsubstituted C1 to C30 alkoxy group, a substituted or unsubstituted C3 to C30 cycloheteroalkyl group, a substituted or unsubstituted C3 to C30 cycloheteroalkenyl group, a substituted or unsubstituted C6 to C30 aryl group, a substituted or unsubstituted C7 to C30 alkylaryl group, a substituted or unsubstituted C6 to C30 aryloxy group, a substituted or unsubstituted C3 to C30 heterocyclic group, a halogen, a cyano group, and/or a combination thereof, but is not limited thereto. In at least one embodiment, the monovalent substituent may be a halogen selected from F, Cl, Br or I; a cyano group; and/or a combination thereof.

As an example, the second repeating unit may be represented by Chemical Formula 2aa.

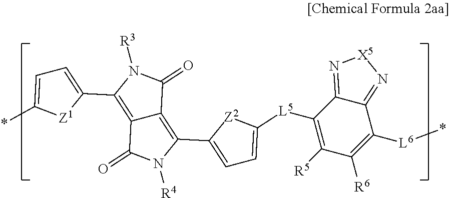

In Chemical Formula 2aa, X⁵, Z¹, Z², L⁵, L⁶, and R³ to R⁶ are the same as described above.

For example, Z¹ and Z² may each independently be O, S, Se, or Te.

For example, L⁵ and L⁶ may each independently be a single bond; a substituted or unsubstituted C6 to C30 arylene group; a substituted or unsubstituted divalent C3 to C30 heterocyclic group including O, S, Se, or Te; a fused ring thereof; and/or a combination thereof.

As described above, the first repeating unit and the second repeating unit may be randomly arranged in the polymer, and the second repeating unit may be included in smaller quantities than the first repeating unit. For example, the second repeating unit may be included in an amount of less than or equal to about 30 mol % based on a total amount of the first repeating unit and second repeating unit. For example, the second repeating unit may be included in an amount of about 1 to about 30 mol %, for example, about 3 to about 30 mol %, about 5 to about 30 mole %, about 7 to 30 mole %, about 10 to about 30 mole %, about 1 to 2 about 8 mole %, about 3 to about 28 mole %, about 5 to about 28 mole %, about 7 to about 28 mole %, about 10 to about 28 mole %, about 1 to about 25 mole %, about 3 to about 25 mole %, about 5 to about 25 mole %, about 7 to about 25 mole %, about 10 to about 25 mole %, about 1 to about 20 mole %, about 3 to about 20 mol %, about 5 to about 20 mol %, about 7 to about 20 mol %, about 10 to about 20 mol %, about 1 to about 15 mol %, about 3 to about 15 mol %, about 5 to about 15 mol %, about 7 to about 15 mol %, and/or about 10 to about 15 mol % based on a total amount of the first repeating unit and second repeating unit.

As an example, the polymer may be represented by Chemical Formula 3.

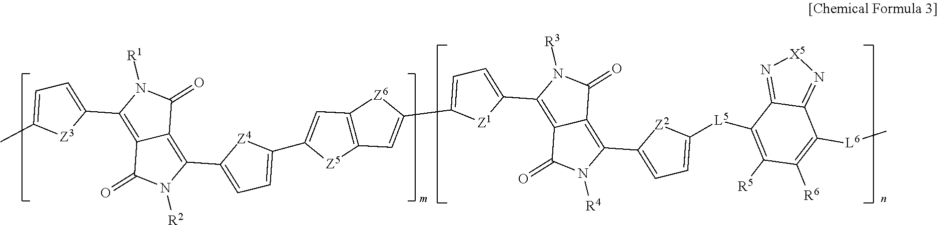

In Chemical Formula 3, X⁵, Z¹ to Z⁶, L⁵, L⁶ and R¹ to R⁶ are the same as described above, and m is a molar ratio of the first repeating unit and n is a molar ratio of the second repeating unit. In at least one example embodiment, 0.5<m<1.0 and 0<n<0.5 may be satisfied, and/or 0.7≤m<1.0 and 0<n≤0.3 may be satisfied. For example, m+n may be 1.

The polymer may be obtained by copolymerizing a first monomer selected to provide at least one electron donating moiety (e.g. D1) and a second monomer and a third monomer selected to provide at least two electron accepting moieties (first and second electron accepting moieties such as A¹ and A²). Accordingly, the polymer may be at least a terpolymer.

In order to obtain the first repeating unit of the aforementioned polymer, the first monomer and the second monomer may have terminal functional groups configured to react with each other. For example, in at least some embodiments, one of the first monomer and the second monomer may have a halogen group as a terminal functional group, and the other of the first monomer and the second monomer may have a metal salt (such as trimethyl tin) as a terminal functional group.

In order to obtain the second repeating unit of the aforementioned polymer, the second monomer capable of providing the first electron accepting moiety and the third monomer capable of providing the second electron accepting moiety have terminal functional groups configured to react with each other. For example, the second monomer may have a metal salt such as trimethyl tin as a terminal functional group, and the third monomer may have a halogen group as a terminal functional group; or the second monomer may have a halogen group as a terminal functional group, and the third monomer may have a metal salt such as trimethyl tin as a terminal functional group. For example, the terminal functional group included in the first monomer may be the same as the terminal functional group included in the third monomer.

By polymerizing these first, second, and third monomers, a portion of the second monomer (providing the first electron accepting moiety) reacts with the first monomer (providing the electron donating moiety) to form the first repeating unit and another portion of the second monomer may react with a third monomer (a second electron accepting moiety) to form a second repeating unit. Additionally, by adjusting a providing ratio of the first, second, and third monomers, the ratio of the first repeating unit and the second repeating unit may also be adjusted. However, the polymerization reaction is not limited to this and may be performed using various monomers in various ratios.

The numbers of first repeating units and second repeating units in a polymer chain included in the polymer may be, for example, 1 to 1000, 1 to 800, 2 to 1000, 2 to 800, 5 to 800, and 5 to 700, 1, 5 to 500, and/or 5 to 300, respectively, but are not limited thereto. For example, an average (e.g., mode) of the sums of the numbers of first and second repeating units in the polymer chains of the polymer may not exceed 2000.

The polymer may further include a third repeating unit in addition to the first and second repeating units described above. For example, the third repeating unit may be different from the first repeating unit and include an electron donating moiety and an electron accepting moiety. For example, the third repeating unit may be different from the second repeating unit and may include a plurality of different electron accepting moieties. For example, the third repeating unit may include a moiety that provides flexibility to the polymer. For example, the third repeating unit may include a moiety that provides stretchability to the polymer.

A weight average molecular weight of the polymer may be, for example, about 5,000 Da to about 500,000 Da, and within the above range, for example, may be about 10,000 Da to about 300,000 Da or about 30,000 Da to about 250,000 Da.

The aforementioned polymers may be formed into a polymer film. For example, the polymer film may be a deposited film formed by vapor deposition and/or a coated film formed by a solution process.

The polymer film may further include a binder and/or an elastomer in addition to the aforementioned polymer. The binder may improve the dispersibility of the aforementioned polymer, and may be, for example, polystyrene, but is not limited thereto. The elastomer may be blended with the aforementioned polymers to provide stretchability, and may be, for example, polyorganosiloxane, polyamide, polyimide, polyamidoimide, polyisobutene, polyolefin, polyester, polyurethane, and/or a combination thereof, but is not limited to thereto.

As an example, the polymer film may be a stretchable polymer film. The stretchable polymer film may flexibly respond to external forces or external movements such as twisting, pressing, and/or pulling due to the stretching characteristics of the polymer described above, and may be easily restored to its original state. The elastic modulus of the stretchable polymer film may be, for example, less than about 107 Pa. For example, the elastic modulus of the stretchable polymer film may be within the above range of greater than or equal to about 10 Pa and less than about 107 Pa. For example, the elongation rate of the stretchable polymer film may be greater than or equal to about 10%, and/or within the above range of about 10% to about 1000%, about 10% to about 800%, about 10% to about 500%, about 10% to about 300%, about 10% to about 200%, about 10% to about 100%, about 10% to about 90%, about 10% to about 80%, about 10% to about 70%, about 10% to about 60%, about 10% to about 50%, about 10% to about 40%, about 20% to about 70%, about 20% to about 60%, about 20% to about 50%, and/or about 20% to about 40%. Herein, the elongation rate may be a percentage of a length change that is increased to a breaking point with respect to the initial length. For example, when the stretchable polymer film is stretched, the change in the electrical characteristics of the stretchable polymer film may be relatively small. For example, when the stretchable polymer film is stretched by about 30%, the change in the charge mobility of the stretchable polymer film may be less than or equal to about 10%, less than or equal to about 8%, less than or equal to about 7%, less than or equal to about 5%, less than or equal to about 3%, or less than or equal to about 2%, and/or less than or equal to about 1%.

Because the polymer film may have good semiconductor characteristics and high charge mobility, the polymer film may be applied to various devices that utilized organic semiconductors.

For example, the polymer film including the aforementioned polymer may be applied to a thin film transistor, and as a charge transport layer and/or an active layer in electronic devices such as solar cells, organic light emitting displays, and organic sensors. The electronic device may be, for example, a flexible and stretchable electronic device, and may be a wearable device and/or a skin-like device.

Hereinafter, an example of a thin film transistor including the aforementioned polymer will be described with reference to the drawings.

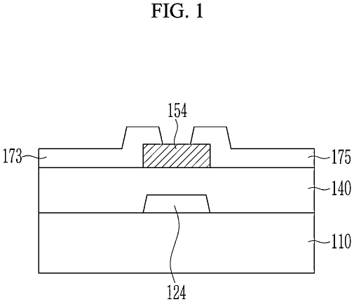

FIGS. 1 to 3 are cross-sectional views each showing thin film transistors according to some embodiments.

Referring to FIGS. 1 to 3, a thin film transistor according to some example embodiments includes a gate electrode 124, an organic semiconductor 154 overlapped with the gate electrode 124, a gate dielectric 140 between the organic semiconductor 154 and the gate electrode 124, and a source electrode 173 and a drain electrode 175 electrically connected to the organic semiconductor 154.

First, referring to FIG. 1, a thin film transistor according to the present embodiment may have a bottom gate and top contact structure. Specifically, a thin film transistor according to the present embodiment includes a gate electrode 124 on the substrate 110; a gate insulating layer 140 on the gate electrode 124; an organic semiconductor 154 on the gate insulating layer 140; and a source electrode 173 and a drain electrode 175 electrically connected to the organic semiconductor 154.

In at least one embodiment, the gate electrode 124 is formed on a substrate 110 made of transparent glass, silicon, plastic, and/or the like. The gate electrode 124 is connected to a gate line (not shown) transferring a gate signal. The gate electrode 124 may be made of a conductive material, such as gold (Au), copper (Cu), nickel (Ni), aluminum (Al), molybdenum (Mo), chromium (Cr), tantalum (Ta), titanium (Ti), an alloy thereof, an organic conductor, and/or a combination thereof.

A gate insulating layer 140 is formed on the gate electrode 124. The gate insulating layer 140 may be made of an organic material and/or an inorganic material. Examples of the organic material may include a soluble polymer compound such as a polyvinyl alcohol-based compound, a polyimide-based compound, a polyacrylic compound, a polystyrene-based compound, and benzocyclobutane (BCB), and examples of the inorganic material may include a silicon nitride (SiNx) and a silicon oxide (SiO2).

An organic semiconductor 154 is formed on the gate insulating layer 140. The organic semiconductor 154 may include the aforementioned polymer and may be the aforementioned polymer film. The organic semiconductor 154 may be formed by preparing the aforementioned polymer in a solution form and using a solution process such as spin coating, slit coating, inkjet printing, and/or the like. The organic semiconductor 154 may also be formed by vacuum deposition or thermal evaporation of the aforementioned polymer.

A source electrode 173 and a drain electrode 175 are formed on the organic semiconductor 154. The source electrode 173 and the drain electrode 175 face each other on the organic semiconductor 154 in the center of the gate electrode 124. The source electrode 173 is electrically connected to the data line (not shown) transferring the data signal. The source electrode 173 and the drain electrode 175 may include a conductive material such as a metal (e.g., at least one of Au, Cu, Ni, Al, Mo, Cr, Ta, Ti, an alloy thereof), an organic conductor, and/or a combination thereof.

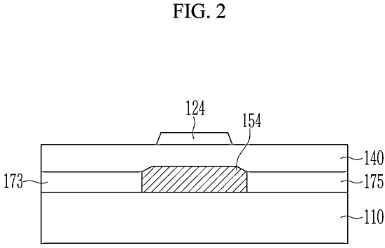

Referring to FIG. 2, the thin film transistor according to the present embodiment may have a top gate and top contact structure, unlike the aforementioned embodiment. Specifically, a thin film transistor according to the present embodiment includes an organic semiconductor 154 on the substrate 110; a source electrode 173 and a drain electrode 175 electrically connected to the organic semiconductor 154; a gate insulating layer 140 on the organic semiconductor 154, the source electrode 173, and the drain electrode 175; and a gate electrode 124 on the gate insulating layer 140, which may otherwise be the same as (or substantially similar to) the corresponding organic semiconductor 154, substrate 110; source electrode 173, drain electrode 175, and gate insulating layer 140 described above, therefore a repeat description thereof shas been omitted for brevity.

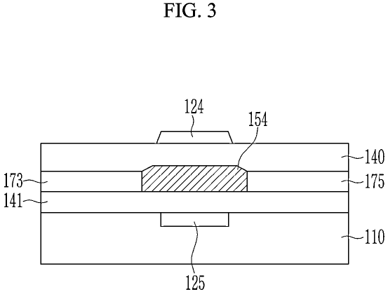

Referring to FIG. 3, the thin film transistor according to the present embodiment may have a dual gate and bottom/top contact structure, unlike the aforementioned embodiments. Specifically, a thin film transistor according to the present embodiment includes an organic semiconductor 154 on the substrate 110; a first gate electrode 125 under the organic semiconductor 154; a first gate dielectric 141 between the first gate electrode 125 under the organic semiconductor 154; a second gate electrode 124 on the organic semiconductor 154; a first gate insulating layer 141 between the organic semiconductor 154 and the first gate electrode 125; a second gate insulating layer 140 between the organic semiconductor 154 and the second gate electrode 124; and a source electrode 173 and a drain electrode 175 electrically connected to the organic semiconductor 154. The organic semiconductor 154, substrate 110; source electrode 173, drain electrode 175, and gate insulating layer 140 of FIG. 3 may otherwise be the same as (or substantially similar to) the corresponding organic semiconductor 154, substrate 110; source electrode 173, drain electrode 175, and gate insulating layer 140 described above, therefore a repeat description thereof has been omitted for brevity.

The first gate electrode 125 may be buried in the substrate 110 or may be formed by impurity doping. The first gate electrode 125, the organic semiconductor 154, and the second gate electrode 124 may be overlapped with each other.

The first gate insulating layer 141 may be made of an organic material and/or an inorganic material. Examples of the organic material may include a soluble polymer compound such as a polyvinyl alcohol-based compound, a polyimide-based compound, a polyacrylic compound, a polystyrene-based compound, and benzocyclobutane (BCB), and examples of the inorganic material may include a silicon nitride (SiNx) and a silicon oxide (SiO2).

Herein, examples of the thin film transistor have been described, but some example embodiments are not limited thereto and may be equally applied to thin film transistors having all structures.

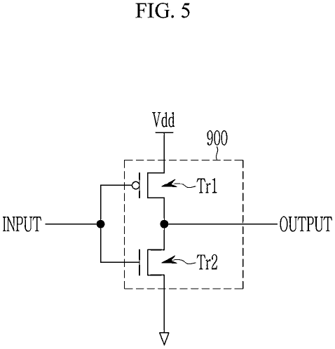

FIG. 5 is a circuit diagram of an inverter according to at least one example embodiment.

Referring to FIG. 5, an inverter 900 may include a p-doped transistor Tr1 and an n-doped transistor Tr2 connected between a power terminal Vdd and a ground terminal. An input node may be connected to the gates of the p-doped transistor Tr1 and the n-type transistor Tr2. An output node may be connected to a node between the p-doped transistor Tr1 and the n-doped transistor Tr2. The inverter 900 may include any one of the thin film transistors in FIGS. 1 to 3 of the present application.

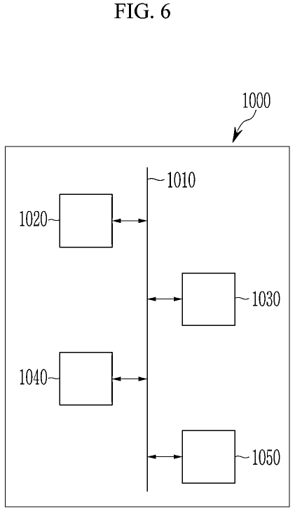

FIG. 6 is a block diagram of an electronic device according to at least one example embodiment.

Referring to FIG. 6, an electronic device 100 may include a processor 1020, a memory 1030, a sensor 1040, and a display 1050 that may be electrically coupled together via a bus 1010. The sensor 1040 may include an organic sensor and/or a biometric sensor and may include any one of the thin film transistors in FIGS. 1 to 3 of the present application. The memory 1030, which may be a non-transitory computer readable medium and may store a program of instructions. The memory 1030 may be a nonvolatile memory, such as a flash memory, a phase-change random access memory (PRAM), a magneto-resistive RAM (MRAM), a resistive RAM (ReRAM), or a ferro-electric RAM (FRAM), or a volatile memory, such as a static RAM (SRAM), a dynamic RAM (DRAM), or a synchronous DRAM (SDRAM). The processor 1020 may execute the stored program of instructions to perform one or more functions. For example, the processor 1020 may be configured to process electrical signals generated by the sensor 1040. The processor 1020 may be configured to generate an output (e.g., an image to be displayed on the display 1050) based on such processing. The display 1050 may include an organic light emitting device. At least one of the processor 1020, the memory 1030, the sensor 1040, and/or the display may include any one of the thin film transistors in FIGS. 1 to 3 of the present application.

One or more of the elements disclosed above may include or be implemented in processing circuitry such as hardware including logic circuits; a hardware/software combination such as a processor executing software; or a combination thereof. For example, the processing circuitry may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The thin film transistor may be applied to a switching and/or driving element of various electronic devices, and the electronic device may be, for example, display devices, semiconductor devices, sensing devices, or lighting devices, for example liquid crystal displays, organic light emitting display devices, quantum dot display devices, electrophoretic display devices, organic photoelectric devices, organic sensors, and/or the like but is not limited thereto. The electronic device including the thin film transistor may be for example flexible and stretchable electronic device, and may be a wearable device and/or a skin-like device.

Hereinafter, some example embodiments are illustrated in more detail with reference to some examples. However, these examples are for purposes of illustration, and the scope of claims is not limited thereto.

### Synthesis Examples of Polymers

### [Polymer 1-A]

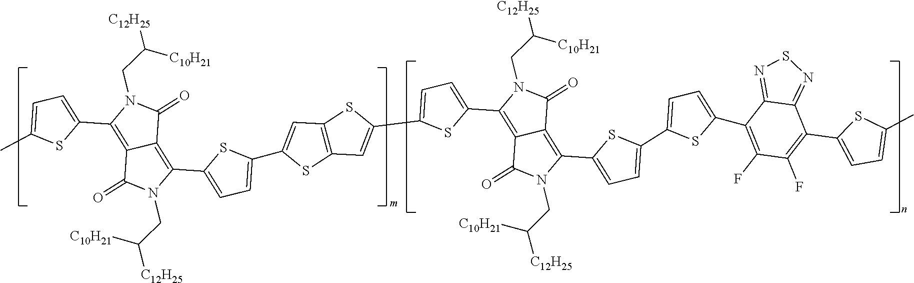

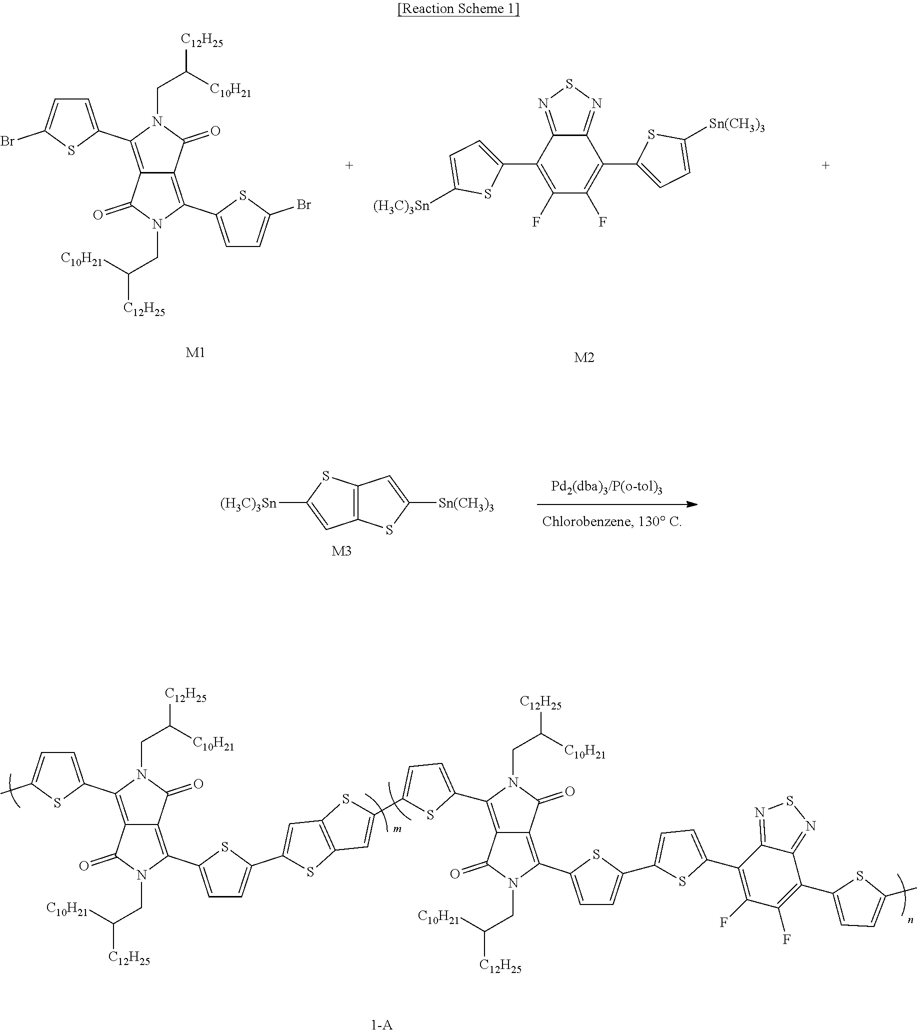

### Synthesis Example 1

226.29 mg (0.2 mmol) of Monomer M1, 13.24 mg (0.02 mmol) of Monomer M2, 83.85 mg (0.18 mmol)) of Monomer M3, 3.66 mg (0.004 mmol) of tri (dibenzylideneacetone) dipalladium (Pd2(dba)3), and 4.87 mg (0.016 mmol) of tris(o-tolyl)phosphine (P(o-tol)3) are dissolved in 10 ml of chlorobenzene in a 50 ml flask under a nitrogen atmosphere and reacted by heating at 130° C. for 24 hours. After the reaction, the resultant is cooled to room temperature, and an excessive amount of methanol is poured thereinto for precipitation. Subsequently, the precipitates are filtered and purified through Soxhlet. The purification through Soxhlet proceeds by using methanol, acetone, n-hexane, dichloromethane, and chloroform in order, and the last solution obtained by dissolved in the chloroform is recovered and precipitated in methanol. Subsequently, the precipitated material is filtered and dried in a vacuum oven to obtain 214 mg of Polymer 1-A.

Polymer 1-A has a first repeating unit and a second repeating unit in a molar ratio (m:n) of 9:1.

Molecular weight analysis: A molecular weight is measured at 160° C. by using an Agilent PL-GPC220 equipment and 1,2,4-trichlorobenzene as an eluent solution.

Number average molecular weight (Mn)=101,140, weight average molecular weight (Mw)=242,609, polydispersity index (PDI)=2.42

### Synthesis Example 2

226.29 mg (0.2 mmol) of Monomer M1, 39.72 mg (0.06 mmol) of Monomer M2, 65.22 mg (0.14 mmol) of Monomer M3, 3.66 mg (0.004 mmol) of tri (dibenzylideneacetone) dipalladium (Pd₂(dba)₃), and 4.87 mg (0.016 mmol) of tris(o-tolyl)phosphine (P(o-tol)₃) are dissolved in 10 ml of chlorobenzene in a 50 ml flask under a nitrogen atmosphere and reacted by heating at 130° C. for 24 hours. After the reaction, the resultant is cooled to room temperature, and an excessive amount of methanol is poured thereinto for precipitation. Subsequently, the precipitates are filtered and purified through Soxhlet. The purification through Soxhlet proceeds by using methanol, acetone, n-hexane, dichloromethane, and chloroform in order, and the last solution obtained by dissolved in the chloroform is recovered and precipitated in methanol. Subsequently, the precipitated material is filtered and dried in a vacuum oven to obtain 222 mg of Polymer 1-A.

Polymer 1-A has a first repeating unit and a second repeating unit in a molar ratio (m:n) of 7:3.

Mn=101,109, Mw=249,442, PDI=2.47

### Reference Synthesis Example

### [Polymer P]

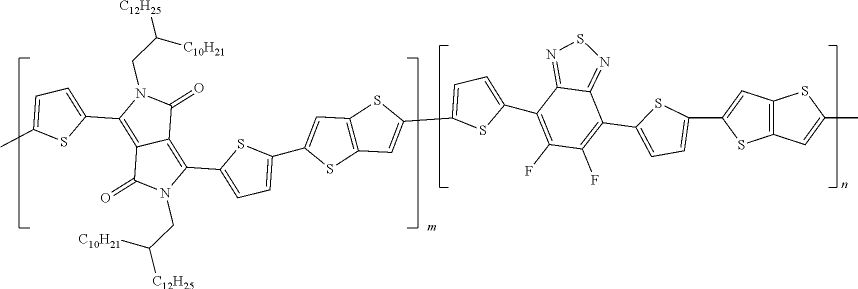

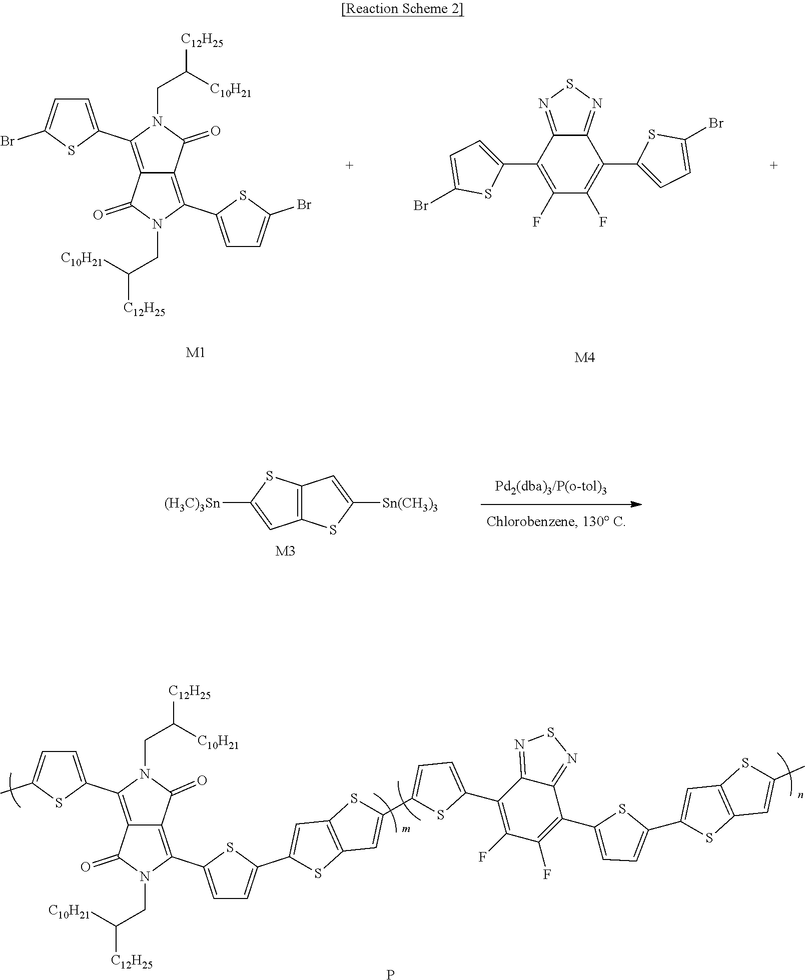

203.66 mg (0.18 mmol) of Monomer M1, 9.88 mg (0.02 mmol) of Monomer M4, 93.17 mg (0.2 mmol) of Monomer M3, 3.66 mg (0.004 mmol) of tri (dibenzylideneacetone) dipalladium (Pd₂(dba)₃), and 4.87 mg (0.016 mmol) of tris(o-tolyl)phosphine (P(o-tol)₃) are dissolved in 10 ml of chlorobenzene in a 50 ml flask under a nitrogen atmosphere and reacted by heating at 130° C. for 24 hours. After the reaction, the resultant is cooled to room temperature, and an excessive amount of methanol is poured thereinto for precipitation. Subsequently, the precipitates are filtered and purified through Soxhlet. The purification through Soxhlet proceeds by using methanol, acetone, n-hexane, dichloromethane, and chloroform in order, and the last solution obtained by dissolved in the chloroform is recovered and precipitated in methanol. Subsequently, the precipitated material is filtered and dried in a vacuum oven to obtain 177 mg of Polymer P.

Polymer P includes a first repeating unit and second repeating unit respectively having an electron donating moiety and an electron accepting moiety, wherein the first repeating unit and the second repeating unit have a molar ratio (m:n) of 9:1.

Mn=96,246, Mw=247,806, PDI=2.57

### Preparation of Polymer Films

### Preparation Example 1

5 mg of the polymer according to Synthesis Example 1 is dissolved in 1 ml of chlorobenzene to prepare a polymer solution. Subsequently, the polymer solution is spin-coated on a quartz substrate at 1500 rpm for 60 seconds and heat-treated at about 190° C. for 1 hour to form a 50 nm-thick polymer film.

### Preparation Example 2

A polymer film is formed in the same manner as in Preparation Example 1 except that the polymer of Synthesis Example 2 is used instead of the polymer of Synthesis Example 1.

### Reference Preparation Example

A polymer film is formed in the same manner as in Preparation Example 1 except that the polymer of Reference Synthesis Example is used instead of the polymer of Synthesis Example 1.

### Evaluation I

The polymer films according to Preparation Examples 1 and 2 and Reference Preparation Example are evaluated with respect to light absorption characteristics.

The light absorption characteristics are measured from an absorption spectrum within a wavelength region of 300 nm to 1200 nm by using a UV-1800 spectrometer (Shimadzu Scientific Instruments).

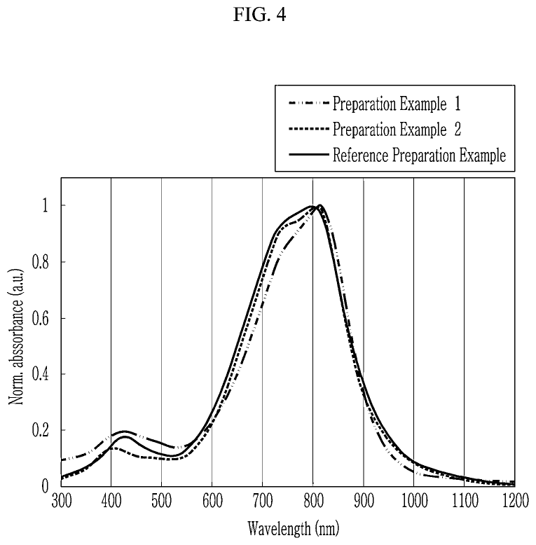

The results are shown in FIG. 4 and Table 1.

FIG. 4 is a graph showing the light absorption characteristics of the polymer films according to Preparation Examples 1 and 2 and Reference Preparation Example.

TABLE 1

| | Peak Absorption | Peak Absorption | |
|---|---|---|---|
| | Wavelength 1 | Wavelength 2 | A(λₚₑₐₖ₂)/ |
| | (λₚₑₐₖ₁, nm) | (λₚₑₐₖ₂, nm) | A(λₚₑₐₖ₁) |
| Preparation Example 1 | 746 | 813 | 1.172 |
| Preparation Example 2 | 741 | 804 | 1.082 |
| Reference Preparation | 734 | 796 | 1.078 |
| Example | | | |

wherein A(λₚₑₐₖ₂)/A(λₚₑₐₖ₁) represents a ratio of absorbance at peak absorption wavelength 2 to absorbance at peak absorption wavelength 1.

In Table 1, the peak absorption wavelength 1 is a wavelength related to H-aggregates of polymer films, and the peak absorption wavelength 2 is a wavelength of J-aggregates of the polymer films.

Referring to FIG. 4 and Table 1, the polymer films of Preparation Examples 1 and 2, compared to the polymer film according to Reference Preparation Example, exhibit a peak absorption wavelength related to J-aggregates in a longer wavelength region, and accordingly, the polymer films of Preparation Examples 1 and 2 are expected to have a more advantageous alignment for transferring charges than the polymer film of Reference Preparation Example.

### Manufacturing of Thin Film Transistors

### Example 1

A self-assembled monolayer (SAM) is formed with octadecyl trichlorosilane (ODTS) on a 300 nm-thick silicon wafer formed of silicon oxide, and a polymer solution prepared by dissolving the polymer of Synthesis Example 1 in chlorobenzene at a concentration of about 1 wt % is spin-coated thereon at 1500 rpm for 60 seconds and then, heat-treated at about 190° C. for 1 hour to form a 50 nm-thick organic semiconductor. Subsequently, on the organic semiconductor, molybdenum oxide (MoOₓ, 0<x≤2)/gold (Au) (10 nm/100 nm) is thermally deposited to form a source electrode and a drain electrode and resultantly, manufacture a thin film transistor. The thin film transistor has a channel width (W) and a channel length (L) of about 100 μm and about 1000 μm, respectively.

### Example 2

A thin film transistor is manufactured in the same manner as in Example 1 except that the polymer of Synthesis Example 2 is used instead of the polymer of Synthesis Example 1 to form the organic semiconductor.

### Reference Example

A thin film transistor is manufactured in the same manner as in Example 1 except that the polymer of Reference Synthesis Example is used instead of the polymer of Synthesis Example 1 to form the organic semiconductor.

### Evaluation II

The thin film transistors according to Examples and Reference Example are evaluated with respect to electrical characteristics.

The electrical characteristics are measured by using Keithley 4200A (SEMI SYSTEM W/2 MPSMU & FPD), while a gate voltage of +10 V to −30 V is applied to the thin film transistors in a standby state.

The results are shown in Table 2.

TABLE 2

| | Bulk mobility | Max. mobility | |
|---|---|---|---|
| | (cm²/Vs) | (cm²/Vs) | Iₒₙ/I_{off} |
| Example 1 | 0.54 | 0.61 | 1.7 × 10⁷ |
| Example 2 | 0.26 | 0.37 | 2.8 × 10⁵ |
| Reference | 0.21 | 0.34 | 1.7 × 10⁵ |
| Example | | | |

Referring to Table 2, the thin film transistors of Examples, compared to the thin film transistor of Reference Example, exhibit improved electrical characteristics.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A polymer comprising:
a first repeating unit represented by Chemical Formula 1; and
a second repeating unit represented by Chemical Formula 2, 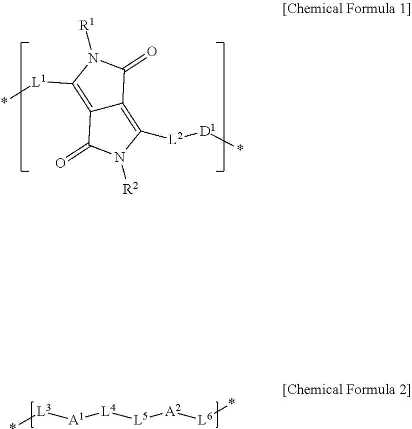
wherein
D¹ is an electron donating moiety,
A¹ and A² are different electron accepting moieties,
L¹ to L⁶ are each independently a single bond, a substituted or unsubstituted C1 to C20 alkylene group, a substituted or unsubstituted C6 to C30 arylene group, a substituted or unsubstituted divalent C3 to C30 heterocyclic group, a fused ring thereof, or a combination thereof,
R¹ and R² are each independently hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C3 to C30 cycloalkenyl group, a substituted or unsubstituted C1 to C30 alkoxy group, a substituted or unsubstituted C3 to C30 cycloheteroalkyl group, a substituted or unsubstituted C3 to C30 cycloheteroalkenyl group, a substituted or unsubstituted C6 to C30 aryl group, a substituted or unsubstituted C7 to C30 alkylaryl group, a substituted or unsubstituted C6 to C30 aryloxy group, a substituted or unsubstituted C3 to C30 heterocyclic group, a halogen, a cyano group, or a combination thereof, and
* is a linking point.

2. The polymer of claim 1, wherein the D¹ is a substituted or unsubstituted C6 to C30 arylene group; a substituted or unsubstituted divalent C3 to C30 heterocyclic group containing at least one of O, S, Se, Te, or Si; a fused ring thereof; or a combination thereof.

3. The polymer of claim 2, wherein the D¹ is one or more substituted or unsubstituted phenylene groups; one or more substituted or unsubstituted naphthylene groups; one or more substituted or unsubstituted anthracenylene groups; one or more substituted or unsubstituted phenanthrenylene groups; one or more substituted or unsubstituted pentagonal rings containing at least one of O, S, Se, Te, or Si; a fused ring of one or more of the substituted or unsubstituted pentagonal rings and one or more of the substituted or unsubstituted phenylene groups; a fused ring of one or more of the substituted or unsubstituted pentagonal rings and one or more of the substituted or unsubstituted naphthylene groups; a fused ring of the one or more of the substituted or unsubstituted pentagonal ring and one or more of the substituted or unsubstituted anthracenylene groups; a fused ring of the one or more of the substituted or unsubstituted pentagonal ring and one or more of the substituted or unsubstituted phenanthrenylene groups; or a combination thereof.

4. The polymer of claim 1, wherein
the L¹ to L⁶ are each independently a single bond; a substituted or unsubstituted C6 to C30 arylene group; a substituted or unsubstituted divalent C3 to C30 heterocyclic group containing at least one of N, O, S, Se, Te, or Si; or a combination thereof, and
each of the L¹ to L⁶ is different from the D¹.

5. The polymer of claim 1, wherein the A¹ and the A² are each independently
a C6 to C30 arylene group, or
a divalent C3 to C30 heterocyclic group containing at least one of nitrogen, carbonyl group, a halogen, or a cyano group.

6. The polymer of claim 1, wherein the A¹ and the A² are each represented by a substituted or unsubstituted divalent cyclic group listed in Group 2: 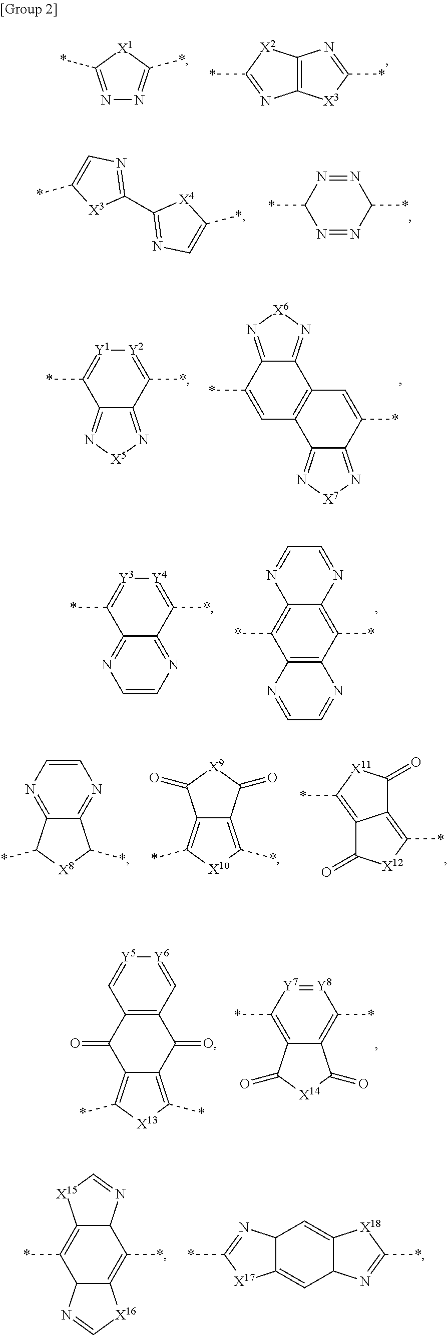 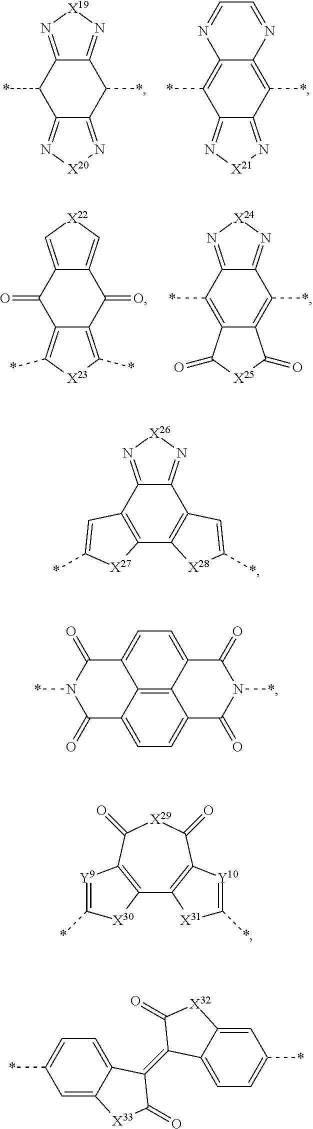 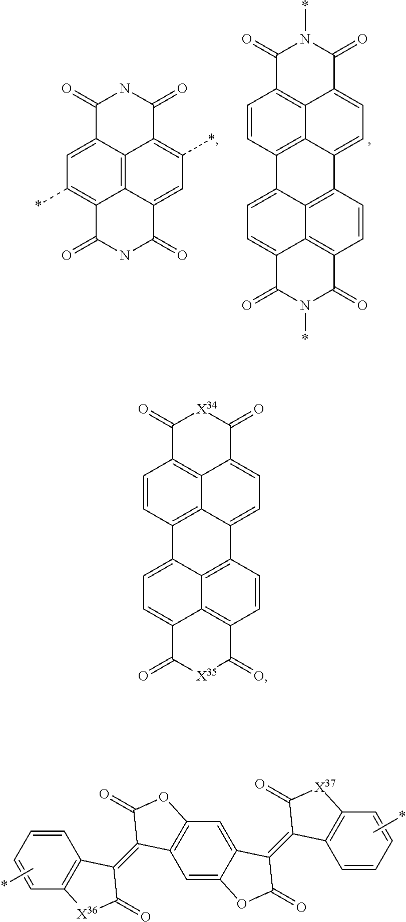
wherein
X¹ to X³⁷ are each independently O, S, Se, Te, NR^{a}, CR^{b}R^{c}, or SiR^{d}R^{e},
Y¹ to Y¹⁰ are each independently CR^{f} or N, and
R^{a} to R^{f} are each independently hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C3 to C30 cycloalkenyl group, a substituted or unsubstituted C1 to C30 alkoxy group, a substituted or unsubstituted C3 to C30 cycloheteroalkyl group, a substituted or unsubstituted C3 to C30 cycloheteroalkenyl group, a substituted or unsubstituted C6 to C30 aryl group, a substituted or unsubstituted C7 to C30 alkylaryl group, a substituted or unsubstituted C6 to C30 aryloxy group, a substituted or unsubstituted C3 to C30 heterocyclic group, a halogen, a cyano group, or a combination thereof.

7. The polymer of claim 1, wherein the second repeating unit is represented by Chemical Formula 2a: 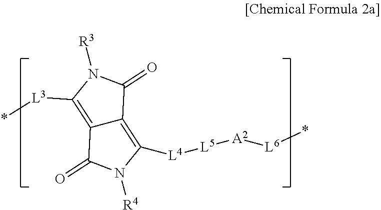
wherein R³ and R⁴ are each independently hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C3 to C30 cycloalkenyl group, a substituted or unsubstituted C1 to C30 alkoxy group, a substituted or unsubstituted C3 to C30 cycloheteroalkyl group, a substituted or unsubstituted C3 to C30 cycloheteroalkenyl group, a substituted or unsubstituted C6 to C30 aryl group, a substituted or unsubstituted C7 to C30 alkylaryl group, a substituted or unsubstituted C6 to C30 aryloxy group, a substituted or unsubstituted C3 to C30 heterocyclic group, a halogen, a cyano group, or a combination thereof.

8. The polymer of claim 7, wherein the A² is represented by substituted or unsubstituted divalent cyclic group listed in Group 2′: 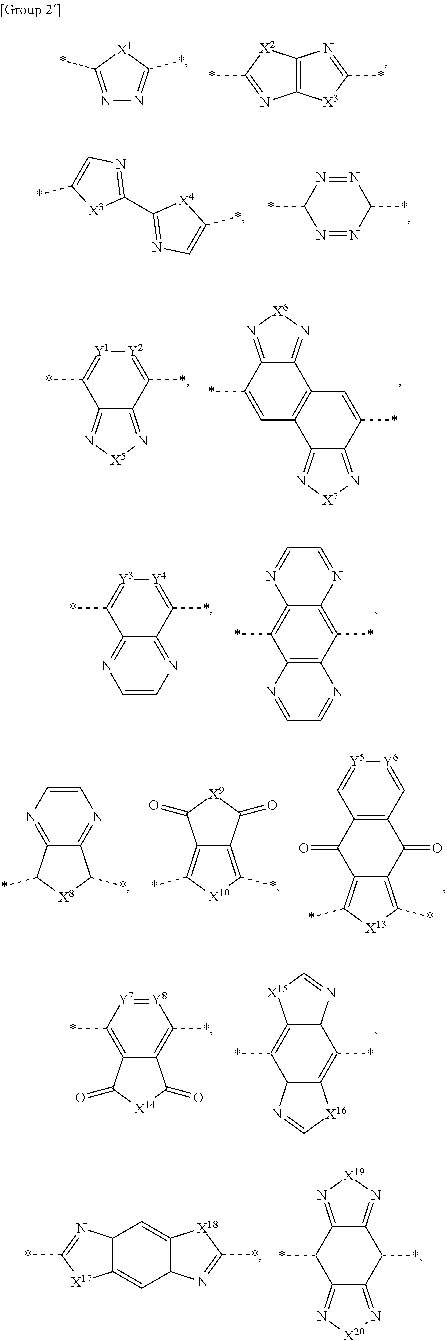 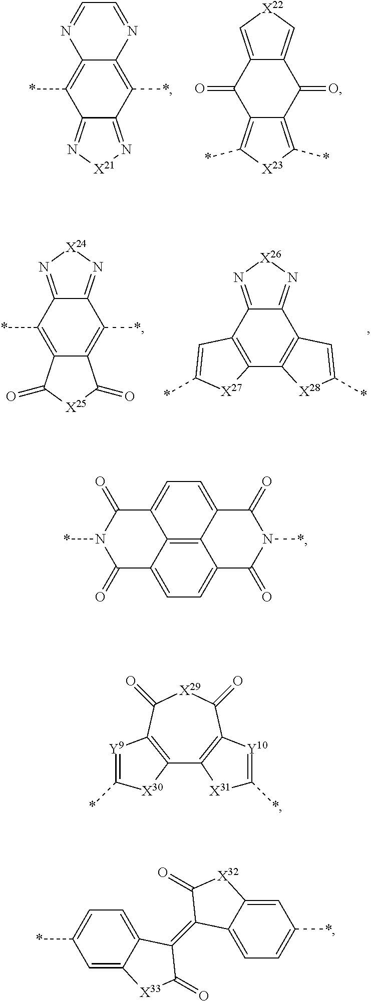 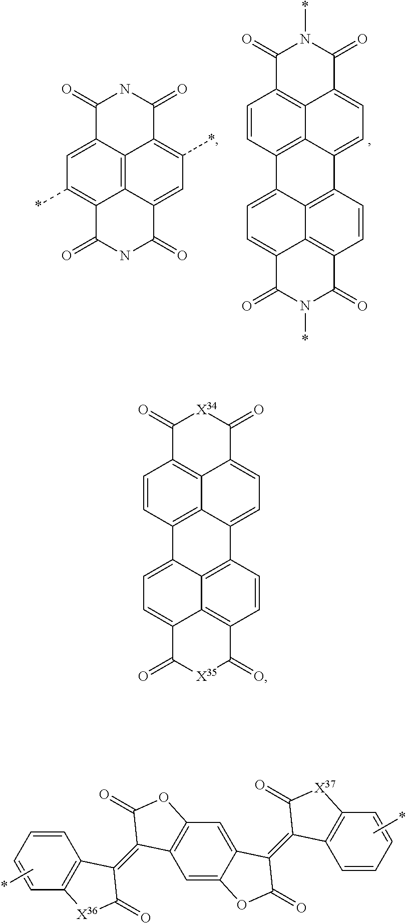
wherein
X¹ to X¹⁰ and X¹³ to X³⁷ are each independently O, S, Se, Te, NR^{a}, CR^{b}R^{c}, or SiR^{d}R^{e},
Y¹ to Y¹⁰ are each independently CR^{f} or N, and
R^{a} to R^{f} are each independently hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C3 to C30 cycloalkenyl group, a substituted or unsubstituted C1 to C30 alkoxy group, a substituted or unsubstituted C3 to C30 cycloheteroalkyl group, a substituted or unsubstituted C3 to C30 cycloheteroalkenyl group, a substituted or unsubstituted C6 to C30 aryl group, a substituted or unsubstituted C7 to C30 alkylaryl group, a substituted or unsubstituted C6 to C30 aryloxy group, a substituted or unsubstituted C3 to C30 heterocyclic group, a halogen, a cyano group, or a combination thereof.

9. The polymer of claim 7, wherein the second repeating unit is represented by Chemical Formula 2aa: 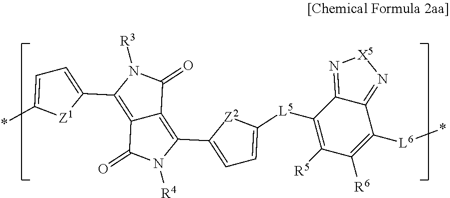
wherein, in Chemical Formula 2aa,
X⁵, Z¹, and Z² are each independently O, S, Se, Te, NR^{a}, CR^{b}R^{c}, or SiR^{d}R^{e}, and
R⁵ to R⁶ and R^{a} to R^{e} are each independently hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C3 to C30 cycloalkenyl group, a substituted or unsubstituted C1 to C30 alkoxy group, a substituted or unsubstituted C3 to C30 cycloheteroalkyl group, a substituted or unsubstituted C3 to C30 cycloheteroalkenyl group, a substituted or unsubstituted C6 to C30 aryl group, a substituted or unsubstituted C7 to C30 alkylaryl group, a substituted or unsubstituted C6 to C30 aryloxy group, a substituted or unsubstituted C3 to C30 heterocyclic group, a halogen, a cyano group, or a combination thereof.

10. The polymer of claim 1, wherein
the first repeating unit and the second repeating unit are randomly arranged in a polymer chain, and
a quantity of the second repeating unit is less than a quantity of the first repeating unit.

11. The polymer of claim 1, wherein the second repeating unit is included in an amount within a range of about 1 to about 30 mol % based on a total of the first repeating unit and the second repeating unit.

12. The polymer of claim 1, wherein the polymer is represented by Chemical Formula 3: 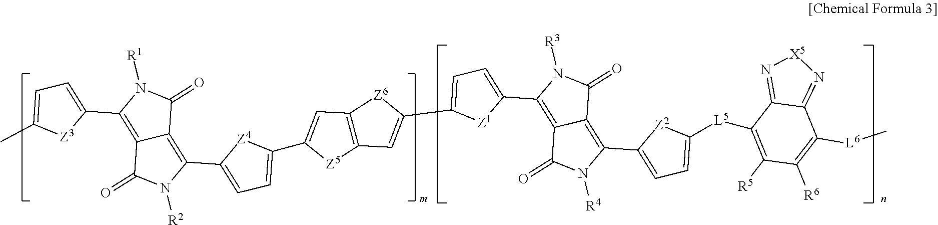
wherein
X⁵ and Z¹ to Z⁶ are each independently O, S, Se, Te, NR^{a}, CR^{b}R^{c}, or SiR^{d}R^{e},
R³ to R⁶ and R^{a} to R^{e} are each independently hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C3 to C30 cycloalkenyl group, a substituted or unsubstituted C1 to C30 alkoxy group, a substituted or unsubstituted C3 to C30 cycloheteroalkyl group, a substituted or unsubstituted C3 to C30 cycloheteroalkenyl group, a substituted or unsubstituted C6 to C30 aryl group, a substituted or unsubstituted C7 to C30 alkylaryl group, a substituted or unsubstituted C6 to C30 aryloxy group, a substituted or unsubstituted C3 to C30 heterocyclic group, a halogen, a cyano group, or a combination thereof, and
0.7≤m<1.0 and 0<n≤0.3.

13. A polymer, the polymer comprising:
a first repeating unit including a first electron accepting moiety and an electron donating moiety; and
a second repeating unit including the first electron accepting moiety and a second electron accepting moiety different from the first electron accepting moiety,
wherein the first repeating unit and the second repeating unit are randomly arranged in a chain, and
a quantity of the second repeating unit is less than a quantity of the first repeating unit.

14. The polymer of claim 13, wherein the first electron accepting moiety and the second electron accepting moiety are each represented by a substituted or unsubstituted divalent cyclic group listed in Group 2: 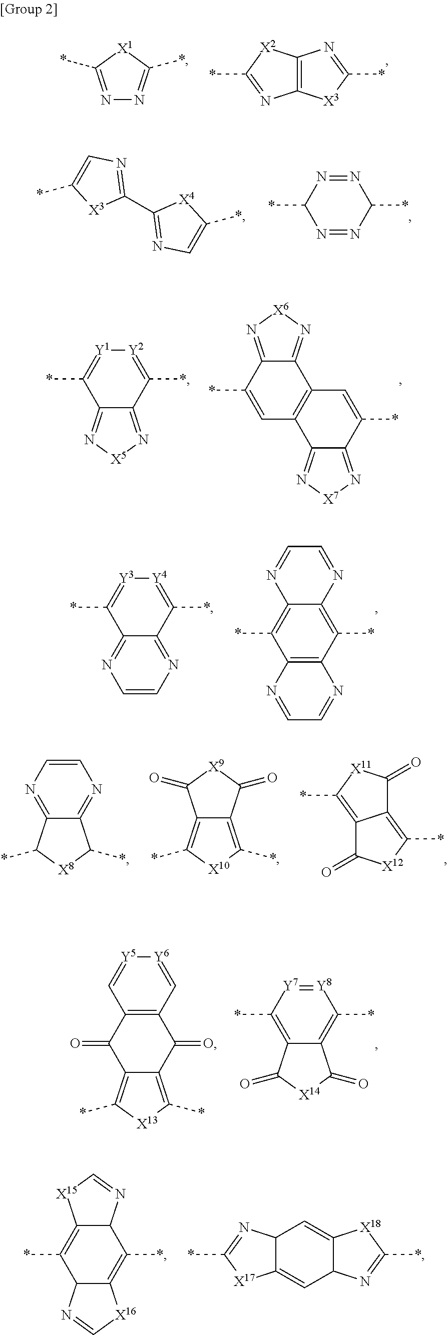 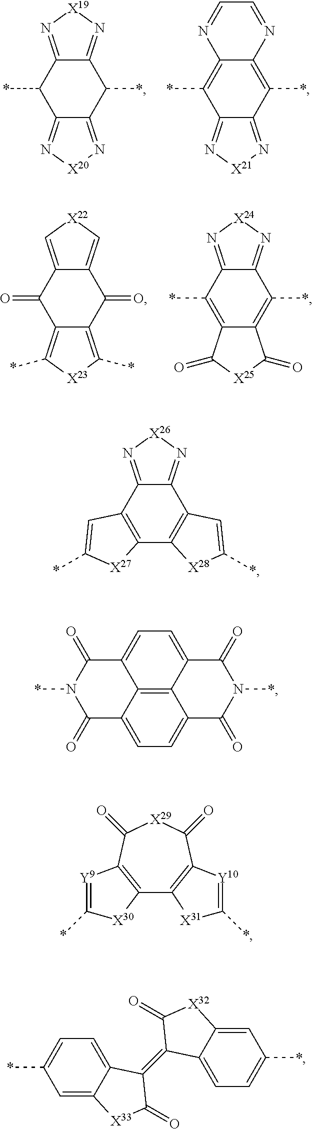 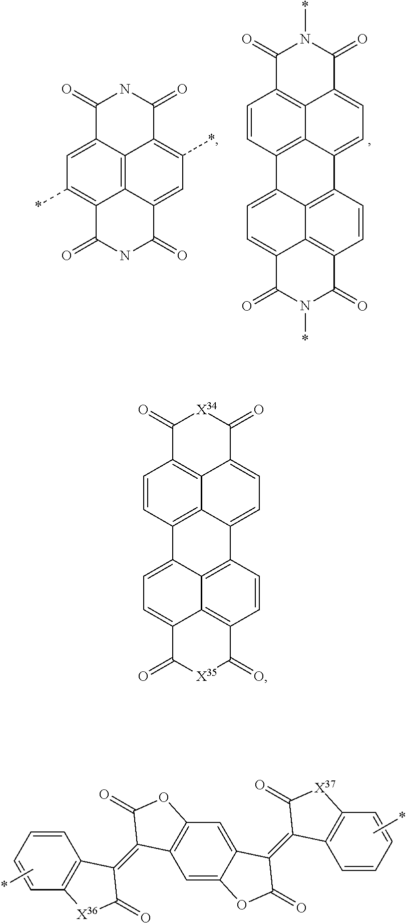
wherein, in Group 2,
X¹ to X³⁷ are each independently O, S, Se, Te, NR^{a}, CR^{b}R^{c}, or SiR^{d}R^{e},
Y¹ to Y¹⁰ are each independently CR^{f} or N,
R^{a} to R^{f} are each independently hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C3 to C30 cycloalkenyl group, a substituted or unsubstituted C1 to C30 alkoxy group, a substituted or unsubstituted C3 to C30 cycloheteroalkyl group, a substituted or unsubstituted C3 to C30 cycloheteroalkenyl group, a substituted or unsubstituted C6 to C30 aryl group, a substituted or unsubstituted C7 to C30 alkylaryl group, a substituted or unsubstituted C6 to C30 aryloxy group, a substituted or unsubstituted C3 to C30 heterocyclic group, a halogen, a cyano group, or a combination thereof, and
* is a linking point.

15. The polymer of claim 13, wherein the electron donating moiety is one or more substituted or unsubstituted phenylene groups; one or more substituted or unsubstituted naphthylene groups; one or more substituted or unsubstituted anthracenylene groups; one or more substituted or unsubstituted phenanthrenylene groups; one or more substituted or unsubstituted pentagonal rings containing at least one of O, S, Se, Te, or Si; a fused ring of one or more of the substituted or unsubstituted pentagonal rings and one or more of the substituted or unsubstituted phenylene groups; a fused ring of the one or more of the substituted or unsubstituted pentagonal rings and one or of the more substituted or unsubstituted naphthylene groups; a fused ring of one or more of the substituted or unsubstituted pentagonal ring and one or more of the substituted or unsubstituted anthracenylene groups; a fused ring of one or more of the substituted or unsubstituted pentagonal ring and one or more of the substituted or unsubstituted phenanthrenylene groups; or a combination thereof.

16. The polymer of claim 13, wherein a molar ratio of the first repeating unit and the second repeating unit is within a range of about 70:30 to about 99:1.

17. The polymer of claim 13, wherein a total molar ratio of the first electron accepting moiety and the second electron accepting moiety in the polymer is about 1.01 to 3 times a molar ratio of the electron donating moiety in the polymer.

18. An electronic device comprising:
a semiconductor layer including the polymer of claim 1.

19. A thin film transistor comprising:
a gate electrode;
an organic semiconductor including the polymer of claim 1 and overlapping the gate electrode; and
a source electrode and a drain electrode electrically connected to the organic semiconductor.

20. An electronic device comprising the thin film transistor of claim 19.
